(19) United States
(12) Patent Application Publication
(10) Pub. No.: US 2004/0008074 A1
(43) Pub. Date: Jan. 15, 2004

(54) Display panel drive circuit

(76) Inventors: Satoshi Takehara, Tokyo (JP); Yoshirou Yamaha, Kanagawa (JP)

Correspondence Address: FINNEGAN, HENDERSON, FARABOW, GARRETT & DUNNER, LLP, 1300 I STREET, NW, WASHINGTON, DC, 20005, US

(21) Appl. No.: 10/399,627

(22) PCT Filed: Aug. 22, 2002
(86) PCT No.: PCT/JP02/08471

(30) Foreign Application Priority Data
Aug. 22, 2001 (JP) 2001-251430
Aug. 22, 2001 (JP) 2001-251431
Aug. 22, 2001 (JP) 2001-251432
Aug. 24, 2001 (JP) 2001-255051
Feb. 19, 2002 (JP) 2002-042284
Mar. 19, 2002 (JP) 2002-077126

(51) Int. Cl. H03K 3/00

(52) U.S. Cl. 327/524

(57) ABSTRACT

To reduce degradation of image quality when constructing anode line drive circuits in a display panel drive circuit from a plurality of IC chips.

Dummy drive output and proper drive output of an adjoining IC chip are switched in predetermined cycles and supplied to an anode line. This makes it possible to reduce variation in adjacent output currents among IC chips. Thus, it is possible to reduce luminance differences in display areas caused by differences in current driving capacity among IC chips and reduce degradation of image quality when an anode line drive circuit is constructed from a plurality of IC chips.

### TECHNICAL FIELD

The present invention relates to a drive circuit for a display panel. More particularly, it relates to a drive circuit for a display panel which consists of self-luminous elements such as electroluminescent elements. Electroluminescent elements include organic electroluminescent elements and inorganic electroluminescent elements. The present invention is suitable for both of them.

### BACKGROUND ART

Organic electroluminescent (hereinafter abbreviated to EL) elements are known as self-luminous elements used to implement thin, low-power consuming display devices. A display device and its drive circuit using EL elements are described in Japanese Patent Laid-Open No. 2001-42821.

FIG. 1 shows schematic configuration of this EL element. As shown in the figure, the EL element is made by laminating a transparent substrate 100 such as a glass substrate on which a transparent electrode 101 is formed; at least one organic functional layer 102 composed of an electron transport layer, luminescent layer, and hole transport layer; and a metal electrode 103.

FIG. 2 is an equivalent circuit diagram showing characteristics of the EL element electrically. The EL element shown in the figure can be replaced by a capacitive component C and a component E which has properties of a diode and is coupled in parallel with the capacitive component.

If a direct current is passed between the transparent electrode 101 and metal electrode 103 with a positive voltage applied to the anode (+pole) of the transparent electrode 101 and a negative voltage applied to the cathode (−pole) of the metal electrode 103, electric charge is accumulated in the capacitive component C. When quantity of the charge exceeds the level of an inherent barrier voltage or luminescence threshold voltage of the EL element, a current starts to flow from an electrode (the anode of the diode component E) to the organic functional layer which carries the luminescent layer and the organic functional layer 102 (see FIG. 1) emits light with intensity proportional to the current.

FIG. 3 shows schematic configuration of an EL display device which displays images using a EL display panel consisting of a plurality of the EL elements arranged in a matrix. In the figure, cathode lines (lines connected to the metal electrode) B₁ to Bₙ carrying a first display line to n-th display line, respectively, and m anode lines (lines connected to the transparent electrode) A₁ to Aₘ intersecting the cathode lines B₁ to Bₙ are formed on an ELDP 10, i.e., an EL display panel. EL elements E₁₁ to Eₙₘ with the above described configuration are formed at respective intersections (n×m intersections) of the cathode lines B₁ to Bₙ and anode lines A₁ to Aₘ. In addition, each of the EL elements E₁₁ to Eₙₘ corresponds to each pixel of the ELDP 10.

A luminescence control circuit 1 converts one screen (n rows×m columns) of input image data into pixel data D₁₁ to Dₙₘ corresponding to the pixels of the ELDP 10, i.e., the EL elements E₁₁ to Eₙₘ, and supplies sequentially them row by row to an anode line drive circuit 2 as shown in FIG. 4. For example, pixel data D₁₁ to D₁ₘ consist of m data bits which specify whether the respective EL elements E₁₁ to E₁ₘ belonging to the first display line of the ELDP 10 should emit light. Each of them indicates “luminescence” when it is at logic “1,” and “non-luminescence” when it is at logic “0.”

The luminescence control circuit 1 supplies a cathode line selection control signal to a cathode line drive circuit 3 in synchronization with row-by-row supply of pixel data as shown in FIG. 4 to scan the first display line to n-th display line of the ELDP 10 in sequence. First, the anode line drive circuit 2 extracts all the data bits with a logic “1” which specifies “luminescence” from the m data bits in the pixel data group. Then, it selects all the anode lines which belong to the “columns” corresponding to the extracted data bits from the anode lines A₁ to Aₘ, and connects a constant current source and supplies a predetermined pixel drive current i only to the selected anode lines.

The cathode line drive circuit 3 selects the cathode line—only one cathode line at a time—which corresponds to the display line indicated by the cathode line selection control signal from among the cathode lines B₁ to Bₙ and connects it to ground potential while applying a predetermined high potential V_{cc} to each of the other cathode lines. The high potential V_{cc} is set approximately equal to the voltage (voltage determined based on quantity of charge of a parasitic capacitance C) across a given EL element which is emitting light of desired luminance.

In this case, a light emission drive current flows between the “columns” connected to the constant current source by the anode line drive circuit 2 and the display lines set to the ground potential by the cathode line drive circuit 3. The EL elements formed at the intersections of the display lines and “columns” emit light according to the light emission drive current. On the other hand, since no current flows between the display lines set to the high potential V_{cc} by the cathode line drive circuit 3 and “columns” connected to the constant current source, the EL elements formed at their intersections remain non-luminescent.

As the above operations are performed based on the pixel data D₁₁ to D₁ₘ, D₂₁ to D₂ₘ, . . . , and Dₙ₁ to Dₙₘ, a screen of the ELDP 10 displays one field of light emission pattern, i.e., an image, according to the input image data.

By the way, recently, for implementation of big-screen display panels, it has become necessary to improve screen resolution by increasing the number of display lines, i.e., the cathode lines B, as well as the number of anode lines A. Thus as the number of cathode lines B and anode lines A increase, so do the scale of the anode line drive circuit 2 and the cathode line drive circuit 3. Therefore, it is feared that when both the circuits are implemented as integrated circuits, increased chip area will result in lower yields. In this connection, it is conceivable to construct the anode line drive circuit 2 and the cathode line drive circuit 3 each from a plurality of IC chips.

For example, it is conceivable to construct the anode line drive circuit 2 from two IC chips 2a and 2b as shown in FIG. 5. When the anode line drive circuit 2 is constructed from the two IC chips 2a and 2b in this way, anode lines A₁ to Aₙ will be driven by the IC chip 2a and anode lines A_{N+1} to Aₘ will be driven by the IC chip 2b as shown in FIG. 6. Incidentally, in FIG. 6, current outputs to the pixel elements, i.e., channel numbers for drive outputs, are denoted by “1” to “N−1,” “N,” “N+1,” “N+2” to “m.”

However, if the anode line drive circuit 2 is constructed from a plurality of IC chips as shown in FIG. 6, manufacturing variations and the like may cause differences among IC chips in the value of the light emission drive current to be supplied to the anode lines. Therefore the differences in the light emission drive current will produce areas with different luminance on the screen of the ELDP 10 and the stepwise change will consequently impair image quality especially on boundaries between these areas.

A technique for solving this problem is described in Japanese Patent Laid-Open No. 2001-42827.

FIG. 7 shows schematic configuration of an EL display device described in the Japanese patent. In the figure, the IC chip 2a functions as a first anode line drive circuit 210 while the IC chip 2b functions as a second anode line drive circuit 220. Cathode lines (lines connected to a metal electrode) B₁to Bₙ carrying a first display line to n-th display line, respectively, and 2m anode lines (lines connected to a transparent electrode) A₁ to A₂ₘ intersecting the cathode lines B₁ to Bₙ are formed on an ELDP 10′, i.e., an EL display panel. EL elements E_{1,1} to E_{n,2m} with the configuration shown in FIG. 1 are formed at respective intersections of the cathode lines B₁ to Bₙ and anode lines A₁ to A₂ₘ. Each of the EL elements E_{1,1} to E_{n,2m} corresponds to each pixel of the ELDP 10′.

A luminescence control circuit 1′ supplies a cathode line selection control signal to a cathode line drive circuit 3 as shown in FIG. 8 to scan the first display line to n-th display line of the ELDP 10′ in sequence. The cathode line drive circuit 3 selects the cathode line—only one cathode line at a time—which corresponds to the display line indicated by the cathode line selection control signal from among the cathode lines B₁ to Bₙ of the ELDP 10′ and connects it to ground potential while applying a predetermined high potential V_{cc} to each of the other cathode lines.

Also, the luminescence control circuit 1′ converts one screen (n rows×2m columns) of input image data into pixel data D_{1,1} to D_{n,2m} corresponding to the pixels of the ELDP 10′, i.e., the EL elements E_{1,1} to E_{n,2m}, and divides the pixel data into those belonging to the first to m-th columns and those belonging to the (m+1)-th to 2m-th columns. Then, the luminescence control circuit 1′ groups the pixel data belonging to the first to m-th columns by display line and supplies the resulting pixel data D_{1,1} to D_{1,m}, D_{2,1} to D_{2,m}, D_{3,1} to D_{3,m}, . . . , and D_{n,1} to D_{n,m} one after another as first drive data G₁₋ₘ to the first anode line drive circuit 210 as shown in FIG. 8. At the same time it groups the pixel data belonging to the (m+1)-th to 2m-th columns by display line and supplies the resulting pixel data D_{1,m+1}to D_{1,2m}, D_{2,m+1} to D_{2,2m}, D_{3,m+1} to D_{3,2m}, . . . , and D_{n,m+1} to D_{n,2m} one after another as second drive data GB₁₋ₘ to the second anode line drive circuit 220 as shown in FIG. 8.

The first drive data GA₁₋ₘ and second drive data GB₁₊ₘ are supplied one after another to the first anode line drive circuit 210 and second anode line drive circuit 220, respectively, in synchronization with the scan line selection control signal as shown in FIG. 8. The first drive data GA₁₋ₘ here consist of m data bits which specify whether the respective m EL elements belonging to the first to m-th columns of each display line of the ELDP 10′ should emit light. Similarly, the second drive data GB₁₋ₘ consist of m data bits which specify whether the respective m EL elements belonging to the (m+1)-th to 2m-th columns of each display line of the ELDP 10′ should emit light. For example, each of the data bits indicates luminescence when it is at logic “1,” and non-luminescence when it is at logic “0.”

FIG. 9 shows internal configuration of drive circuits, namely, the first anode line drive circuit 210 and second anode line drive circuit 220. The first anode line drive circuit 210 and second anode line drive circuit 220 are constructed in different two IC chips (see FIG. 5). In FIG. 9, the first anode line drive circuit 210 comprises a reference current control circuit RC, a control current output circuit CO, and a switch block SB as well as transistors Q₁ to Qₘ and resistors R₁ to Rₘ serving as m current drive sources.

The emitter of a transistor Q_{b} in the reference current control circuit RC is connected with a predetermined pixel drive voltage V_{HE} via a resistor Rᵣ while the base and collector are connected with the collector of a transistor Qₐ. A predetermined reference voltage V_{REF} and emitter potential of the transistor Qₐ are fed into an operational amplifier OP. Output potential of the operational amplifier OP is fed into the base of the transistor Qₐ. The emitter of the transistor Qₐ is connected to ground potential via a resistor Rₚ. With the above configuration, a reference current I_{REF} (=V_{REF}/Rₚ) flows between the collector and emitter of the transistor Qₐ.

The pixel drive voltage V_{HE} is applied to the emitters of the transistors Q₁ to Qₘ via the resistors R₁ to Rₘ, respectively. Besides, the bases of the transistors are connected with the base of the transistor Q_{b}. The resistor Rᵣ and resistors R₁ to Rₘ have the same resistance value and the transistors Q₁ to Qₘ, Qₐ and Q_{b} have the same characteristics. Consequently, the reference current control circuit RC and transistors Q₁ to Qₘ compose a current mirror circuit (hereinafter referred to as a current mirror). Thus, a light emission drive current i with the same current value as the reference current I_{REF} is output, flowing between the emitter and collector of each of the transistors Q₁ to Qₘ by mirror effect.

The switch block SB contains m switching elements S₁ to Sₘ which conduct the light emission drive current i outputted from the transistors Q₁ to Qₘ to output terminals X₁ to Xₘ, respectively. In the switch block SB of the first anode line drive circuit 210, the switching elements S₁ to Sₘ are turned on and off separately according to the logical state of the respective first drive data GA₁ to GAₘ supplied from the luminescence control circuit 1′.

For example, when the first drive data GA₁ is at logic “0,” the switching element S₁ is OFF. On the other hand, when the first drive data GA₁ is at logic “1,” the switching element S₁ turns on to conduct the light emission drive current i supplied from the transistor Q₁ to the output terminal X₁. Also, when the first drive data GAₘ is at logic “0,” the switching element Sₘ is OFF. On the other hand, when the first drive data GAₘ is at logic “1,” the switching element Sₘ turns on to conduct the light emission drive current i supplied from the transistor Qₘ to the output terminal Xₘ. In this way, the light emission drive current i outputted from the transistors Q₁ to Qₘ is supplied to the respective anode lines A₁ to Aₘ of the ELDP 10′ via the respective output terminals X₁ to Xₘ as shown in FIG. 7.

A pixel drive voltage V_{BE} is applied to the emitter of a transistor Q₀ in the control current output circuit CO via a resistor R₀. Besides, the base of the transistor Q₀ is connected with the base of the transistor Q_{b} in the reference current control circuit RC. The resistor R₀ has the same resistance value as the resistor Rᵣ in the reference current control circuit RC. And the transistor Q₀ has the same characteristics as the transistors Qₐ and Q_{b} in the reference current control circuit RC. Consequently, the transistor Q₀ in the control current output circuit CO and the reference current control circuit RC compose a current mirror. Thus, the same amount of current as the reference current I_{REF} flows between the collector and emitter of each of the transistor Q₀. The control current output circuit CO supplies this current as control current ic to an input terminal Iᵢₙ of the second anode line drive circuit 22 via an output terminal Iₒᵤₜ. In other words, the same current as the light emission drive current i supplied to the anode lines A₁ to Aₘ of the ELDP 10′ by the first anode line drive circuit 210 is supplied as the control current ic to the second anode line drive circuit 220.

The second anode line drive circuit 220 comprises a drive current control circuit CC and a switch block SB as well as transistors Q₁ to Qₘ and resistors R₁ to Rₘ serving as m current drive sources. The collector and base of a transistor Q_{c} in the drive current control circuit CC are connected with the input terminal Iᵢₙ while the emitter is connected to the ground potential via a resistor R_{Q1}. Consequently, the control current ic outputted from the first anode line drive circuit 210 flows between the collector and emitter of the transistor Q_{c} via the input terminal Iᵢₙ.

The pixel drive voltage V_{BE} is supplied to the emitter of a transistor Qₑ in the drive current control circuit CC via a resistor R_{S}. Besides, the base and collector of the transistor Qₑ is connected with the collector of a transistor Q_{d}. The base of the transistor Q_{d} is connected with the collector and base of the transistor Q_{c} while the emitter is connected to the ground potential via a resistor R_{Q2}. The transistors Q_{c}, Q_{d}, and Qₑ have the same characteristics as the transistor Q₀ in the first anode line drive circuit 210 while the resistor R_{S} has the same resistance value as the resistor R₀ in the first anode line drive circuit 210. Consequently, the same current as the control current ic outputted from the first anode line drive circuit 210 flows between the collector and emitter of the transistor Q_{d}.

The pixel drive voltage V_{BE} is supplied to the emitters of the transistors Q₁ to Qₘ in the second anode line drive circuit 220 via the resistors R₁ to Rₘ, respectively. Besides, the bases of the transistors are connected with the base of the transistor Qₑ. The resistor R_{S} and resistors R₁ to Rₘ have the same resistance value and the transistors Q₁ to Qₘ, Q_{d}, and Qₑ have the same characteristics. Consequently, the drive current control circuit CC and transistors Q₁ to Qₘ compose a current mirror. Thus, the light emission drive current i equal in amount to the control current ic supplied from the first anode line drive circuit 210 is output, flowing between the emitter and collector of each of the transistors Q₁ to Qₘ. The amount of the light emission drive current i outputted from the transistors Q₁ to Qₘ in the second anode line drive circuit 220 is adjusted by the drive current control circuit CC so that it will be equal to that of the light emission drive current outputted from the first anode line drive circuit 210.

The switch block SB contains m switching elements S₁ to Sₘ, which conduct the light emission drive current i outputted from the transistors Q₁ to Qₘ to the output terminals X₁ to Xₘ, respectively. In the switch block SB of the second anode line drive circuit 220, the switching elements S₁ to Sₘ are turned on and off separately according to the logical state of the respective second drive data GB₁ to GBₘ supplied from the luminescence control circuit 1′.

For example, when the second drive data GB₁ is at logic “0,” the switching element S₁ is OFF. On the other hand, when the second drive data GB₁ is at logic “1,” the switching element S₁ turns on to conduct the light emission drive current i supplied from the transistor Q₁ to the output terminal X₁. Also, when the second drive data GBₘ is at logic “0,” the switching element Sₘ is OFF. On the other hand, when the second drive data GBₘ is at logic “1,” the switching element Sₘ turns on to conduct the light emission drive current i supplied from the transistor Qₘ to the output terminal Xₘ. In this way, the light emission drive current i outputted from the transistors Q₁ to Qₘ in the second anode line drive circuit 220 is supplied to the respective anode lines Aₘ₊₁ to A₂ₘ of the ELDP 10′ via the respective output terminals X₁ to Xₘ as shown in FIG. 7.

As described above, with the drive circuit described in the above patent, in addition to the current source (transistors Q₁ to Qₘ) for generating the light emission drive current, the anode line drive circuits contain the drive current control circuit CC for maintaining the amount of the light emission drive current at a level appropriate to inputted control current and the control current output circuit CO for outputting the light emission drive current itself as control current. When the anode lines of a display panel are driven by a plurality of anode line drive circuits each constructed in a separate IC chip, the first anode line drive circuit controls the amount of light emission drive current to be output based on the light emission drive current actually output by the second anode line drive circuit. Thus, even if there are variations in characteristics between the IC chips (serving as the anode line drive circuits), the amounts of light emission drive currents outputted from the individual IC chips will be approximately equal, producing uniform emission luminance on the display panel.

The technique described in the above patent uses a current mirror to transfer the reference current from the first anode line drive circuit 210 consisting of an IC chip to the second anode line drive circuit 220 consisting of another IC chip. Thus, any current variation in the current mirror will cause variation in output current between the IC chips, failing to provide uniform emission luminance on the display panel.

FIG. 10 shows a current mirror composed of N+1 MOS (Metal Oxide Semiconductor) transistors.

As shown in FIG. 10, the current mirror circuit comprises a current source I_{org} as well as the N+1 MOS transistors P_{OUT0}, P_{OUT1}, . . . , and P_{OUTN}. Of the N+1 MOS transistors, one MOS transistor P_{OUT0} constitutes a reference current source for the current mirror in conjunction with the current source I_{org}. The output currents from the other N MOS transistors are used as drive output for the display panel. In this example, the outputs from the other N MOS transistors P_{OUT1} to P_{OUTN} are merged into an output current Iₒᵤₜ for use as drive output.

Assume that all the N+1 MOS transistors P_{OUT0} to P_{OUTN} have the same size. Then, the current ratio, i.e., the ratio of the current derived by the MOS transistor P_{OUT0} to the current derived by the other N MOS transistors P_{OUT1} to P_{OUTN}, is 1:N. The output current Iₒᵤₜ at this time is given by Iₒᵤₜ=N×I_{org}

Generally, current variation ΔI depends on the size of MOS transistors. When the size of MOS transistors is small, the current variation ΔI is large. Conversely, when the size of MOS transistors is large, the current variation ΔI is small.

In the case of MOS transistors used to drive display panels, MOS transistors which correspond to the second proportional “N” in the above current ratio “1:N” are far larger in size than the MOS transistor which corresponds to the first proportional “1.” For example, N>10. Thus, the current variation ΔI is mostly attributable to a variation in current generated from the MOS transistor P_{OUT0} which corresponds to the first proportional “1.”

It is also conceivable to reduce the current ratio of the current mirror, for example, to 2:N/2 or 3:N/3. This will reduce the current variation ΔI. However, since there are as many channels as there are anode lines, the amount of current of the current source I_{org} must be increased, resulting in increased power consumption of the IC chips.

A current DAC (digital analog converter) circuit is sometimes used as the constant current source for the anode line drive circuit 2 described above. This requires a current DAC circuit with as many channels as there are anode lines. Configuration of such a current DAC circuit is shown in FIG. 11.

The current DAC circuit shown in FIG. 11 can be divided into a BIAS portion B and a DAC portion D. A transistor which acts as the BIAS portion B is connected directly to a reference current source I_{ref} for the current mirror. On the other hand, transistors other than the one which acts as the BIAS portion B operate as a DAC circuit to generate the output current Iₒᵤₜ which constitutes a drive signal to be supplied to pixels. This configuration makes it possible to vary data signals (D0 to Dn) sent to the DAC portion D and thereby vary the current mirror ratio and generate the output current Iₒᵤₜ which constitutes analog data.

A multi-channel current DAC circuit can be configured to have a plurality of BIAS portions and a plurality of DAC portions or to have a single BIAS portion and a plurality of DAC portions.

A circuit shown in FIG. 12 is configured to have a plurality of BIAS portions and a plurality of DAC portions. Each BIAS portion gives a bias signal to a corresponding DAC portion. In this case, the circuit, in which the BIAS portions and DAC portions are located in close proximity to each other, has the advantage of not being affected by a tendency of Vₜₕ in the IC chip or voltage drops due to long wiring.

However, since a current mirror circuit exists on each channel, shifts in drain voltages of transistors will cause systematic shifts in current values. This is because the drain current given by the following equation is shifted slightly by the effect of λ when the drain voltage varies even if the transistors are saturated.

I_{DS}=K(V_{GS}−Vₜₕ)²·(1+λV_{DS})

Also, random current variation ΔI is generated which depends on transistor size and Vₒₙ. Thus, this configuration has the disadvantage that the output current Iₒᵤₜ of each channel varies. The variation in this case constitutes current variation between adjacent channels.

On the other hand, a circuit shown in FIG. 13 is configured to have a single BIAS portion and a plurality of DAC portions. Thus, the single BIAS portion supplies bias signals to the plurality of DAC portions. In this case since a current mirror circuit is common to all the channels, this configuration can suppress the systematic shift in current value caused by shift in drain voltage of transistors and the random variation ΔI in current values which depend on the size of transistors and Von. This is because the number of times of mirroring is reduced. Thus, this configuration has the advantage that the variation in the output current Iₒᵤₜ of each channel is suppressed.

However, the circuit, in which the distance between the BIAS portion and DAC portions varies among channels, has the disadvantage of being affected by a tendency of Vₜₕ in the IC chip or voltage drops due to long wiring. The variation in this case constitutes trended variation in output currents in the IC chip.

As described above, each of the circuit configurations in FIGS. 12 and 13 has its own advantages and disadvantages. When adopting a circuit configuration with a single BIAS portion and a plurality of DAC portions and with small variations between adjacent channels as shown in FIG. 13, in particular, it is desired to reduce the trended variation which can occur in the output currents in the IC chip.

A first object of the present invention is to reduce degradation of image quality when constructing anode line drive circuits in a display panel drive circuit from a plurality of IC chips.

A second object of the present invention is to reduce current variation which occurs in a current mirror in anode line drive circuits and eliminate variation in reference voltage among a plurality of IC chips.

A third object of the present invention is to reduce current variation in a display panel drive circuit without increasing power consumption of IC chips.

A fourth object of the present invention is to reduce trended variation in output currents in the IC chip in a display panel drive circuit as well as to reduce variation between adjacent channels by implementing an accurate DAC circuit.

### DISCLOSURE OF THE INVENTION

A display panel drive circuit according to the present invention supplies current to a plurality of drive line groups for driving a plurality of pixel elements which compose a display panel, characterized in that current which flows through each of the plurality of drive line groups is switched in predetermined cycles. The plurality of pixel elements which compose the display panel are electroluminescent elements.

The plurality of drive line groups may be constructed in a plurality of different IC chips and each of the plurality of IC chips may comprise a plurality of drive current supplying means for supplying a drive current to each of the plurality of IC chips and switching means for switching correspondence between the plurality of IC chips and the plurality of drive current supplying means in predetermined cycles. The display panel drive circuit is characterized in that the switching means is formed in the IC chips.

Of the plurality of drive line groups, first and second drive line groups may be provided in a first and second IC chips, respectively; and

the switching means may receive a first drive output belonging to a drive output group of the first IC chip and a second drive output belonging to a drive output group of the second IC chip and supply them to a drive line which belongs to the first drive line group and adjoins the second drive line group by switching between them in predetermined cycles.

The second IC chip may have a dummy drive output which does not correspond to any of the drive lines composing the second drive line group and the dummy drive output may be fed as the second drive output into the switching means.

The display panel drive circuit may further comprise a reference current source shared by the plurality of drive current supplying means, with the reference current source and drive current supplying means composing a current mirror circuit.

The plurality of IC chips are three or more in number and the correspondence between the drive current supplying sources and the IC chips may be switched in rotation in predetermined cycles.

The display panel drive circuit may comprise a plurality of reference current sources each of which generates a reference current; a plurality of drive current generating means for forming a current mirror circuit in conjunction with the plurality of drive current sources to generate current and driving the first and second drive line groups; and switching means for switching correspondence between the plurality of reference current sources and the plurality of drive current generating means in predetermined cycles. The plurality of reference current sources and the plurality of drive current generating means may be contained in a plurality of IC chips.

The switching means may switch electrical connection between the plurality of reference current sources and plurality of IC chips using pulses with a duty ratio of 1/N, where N is the number of IC chips.

The display panel drive circuit may comprise a plurality of digital-to-analog converter portions and a single biasing portion which gives bias signals to the digital-to-analog converter portions; supply a plurality of output currents derived from the plurality of digital-to-analog converter portions to the plurality of drive line groups; and comprise switching means for switching correspondence between the plurality of digital-to-analog converter portions and the plurality of derived output currents in a time-divided manner. The switching means may comprise a plurality of switches corresponding to the plurality of digital-to-analog converter portions and switch correspondence between the plurality of digital-to-analog converter portions and the plurality of derived output currents in a time-divided manner by operating the plurality of switches in sequence.

Another display panel drive circuit according to the present invention supplies current to a plurality of IC chips and drives the display panel by the supplied current, characterized by comprising drive current supplying means for supplying drive current to each of the plurality of IC chips; and switching means for switching correspondence between the IC chips and the drive current supplying means in predetermined cycles.

The display panel drive circuit may further comprise a reference current source shared by the drive current supplying means, with the reference current source and drive current supplying means composing a current mirror circuit.

The plurality of IC chips are three or more in number and the correspondence between the drive current supplying sources and the IC chips may be switched in rotation in predetermined cycles.

The display panel may be composed of a plurality of electroluminescent elements driven by drive output produced by the respective IC chips.

Another display panel drive circuit according to the present invention comprises first and second IC chips and supplies drive output groups from the first and second IC chips to first and second IC drive line groups for driving a plurality of pixel elements which compose the display panel, characterized by comprising a switching circuit which receives a first drive output belonging to a drive output group of the first IC chip and a second drive output belonging to a drive output group of the second IC chip and supplies them to a drive line which belongs to the first drive line group and adjoins the second drive line group by switching between them in predetermined cycles. The switching means may be formed in the first IC chips.

The second IC chip may have a dummy drive output which does not correspond to any of the drive lines composing the second drive line group and the dummy drive output may be fed as the second drive output into the switching means.

The plurality of pixel elements which compose the display panel are characterized by being electroluminescent elements.

Another display panel drive circuit according to the present invention provides current for driving a plurality of pixel elements which compose a display panel, comprising: one transistor which serves as a reference current source; N transistors (N is a natural number) which compose a current mirror circuit in conjunction with the one transistor; and switching means for selecting a transistor to serve as a reference current source from the N+1 transistors and switching to it periodically, characterized in that outputs from the remaining N transistors are derived as drive output for the display panel. The outputs from the remaining N transistors may be merged into one when derived as drive output for the display panel.

The display panel may be composed of a plurality of electroluminescent elements driven by the drive output.

Another display panel drive circuit according to the present invention comprises a plurality of reference current sources each of which generates a reference current; and a plurality of drive current generating means which generate current by mirroring the plurality of reference current sources and provide current for driving a plurality of pixel elements which compose a display panel, characterized in that the drive current generating means are contained in a plurality of IC chips and comprise switching means for switching correspondence between the plurality of reference current sources and the plurality of IC chips in predetermined cycles. The switching means switches electrical connection between the plurality of reference current sources and plurality of IC chips using pulses with a duty ratio of 1/N, where N is the number of IC chips.

The display panel may be composed of electroluminescent elements driven by drive output produced by the respective IC chips.

Another display panel drive circuit according to the present invention is characterized in that: at least one of a plurality of transistors supplies bias signals being connected directly with a reference current source for a current mirror while the other transistors operate as a circuit which generates drive signals to be supplied to pixels using the bias signals; and the display panel drive circuit, characterized in that it comprises a switching means for switching sequentially, in a time-divided manner, the transistor which supplies the bias signals. The switching means comprises a plurality of switches corresponding to each of the plurality of transistors;

at least one of the plurality of switches operates so that the corresponding transistor is connected with the reference current source to act as a mirror source of a current mirror circuit; and

all the other switches are operated so that their corresponding transistors conduct to act as circuits for generating the drive signals.

Another display panel drive circuit according to the present invention is characterized in that it: comprises a plurality of digital-to-analog converter portions and a single biasing portion which gives bias signals to the digital-to-analog converter portions; supplies a plurality of output currents derived from the plurality of digital-to-analog converter portions to pixels to drive a display panel; and comprises switching means for switching correspondence between the plurality of digital-to-analog converter portions and the plurality of derived output currents in a time-divided manner. The switching means may be characterized in that it comprises a plurality of switches corresponding to the plurality of digital-to-analog converter portions and switch correspondence between the plurality of digital-to-analog converter portions and the plurality of derived output currents in a time-divided manner by operating the plurality of switches in sequence.

### BRIEF DESCRIPTION OF THE DRAWINGS

FIG. 1 is a schematic configuration of an EL element;

FIG. 2 is an equivalent circuit diagram showing characteristics of the EL element electrically;

FIG. 3 is a schematic configuration of an EL display device which displays images using a display panel consisting a plurality of the EL elements arranged in a matrix;

FIG. 4 is a diagram showing the timing for supplying pixel data and a scan line selection signal;

FIG. 5 is a diagram showing an anode line drive circuit constructed from two IC chips;

FIG. 6 is a diagram showing correspondence between drive outputs of an anode line drive circuit and anode lines;

FIG. 7 is a diagram showing an anode line drive circuit constructed from two IC chips;

FIG. 8 is a diagram showing the timing for a luminescence control circuit to supply pixel data and a cathode line selection control signal;

FIG. 9 is a diagram showing an exemplary internal configuration of an anode line drive circuit;

FIG. 10 is a diagram showing configuration of a typical current mirror circuit constructed using MOS transistors;

FIG. 11 is a diagram showing configuration of a current DAC circuit used as a constant current source for an anode line drive circuit;

FIG. 12 is a diagram showing a multi-channel current DAC circuit which has a plurality of BIAS portions and a plurality of DAC portions;

FIG. 13 is a diagram showing a multi-channel current DAC circuit which has a single BIAS portion and a plurality of DAC portions;

FIG. 14 is a diagram showing main components of a first embodiment of a display panel drive circuit according to the present invention;

FIG. 15 is a timing chart showing the timing of drive switching made by the display panel drive circuit shown in FIG. 14;

FIG. 16 is a diagram showing relationship between channel numbers of anode lines and output current;

FIG. 17(a) is a diagram showing a configuration example of a switching circuit for an anode line;

FIG. 17(b) is a timing chart showing operations of various parts shown in FIG. 17(a);

FIG. 18 is a diagram showing main components of a second embodiment of a display panel drive circuit according to the present invention;

FIG. 19(a) is a timing chart showing switch timing of switching circuits;

FIG. 19(b) is a timing chart showing the timing to switch among three drive current sources in rotation among three IC chips;

FIG. 20 is a diagram showing how a reference current generating circuit is connected with a first and second anode line drive circuits;

FIG. 21 is a diagram showing a configuration example of switching circuits;

FIG. 22 is a diagram showing main components of a third embodiment of a display panel drive circuit according to the present invention;

FIG. 23 is a timing chart showing switch timing of switching circuits;

FIG. 24 is a diagram showing a configuration example of the switching circuits shown in FIG. 22;

FIG. 25 is a diagram showing main components of a fourth embodiment of a display panel drive circuit according to the present invention;

FIG. 26 is a diagram showing a configuration example of the switching circuits shown in FIG. 25;

FIG. 27 is a block diagram showing main components of a fifth embodiment of a display panel drive circuit according to the present invention;

FIG. 28 is a diagram showing an example of timing to switch correspondence between outputs of DAC portions and output currents;

FIG. 29(a) is a diagram showing a four-stage ring counter;

FIG. 29(b) is a waveform diagram showing output signals of the four-stage ring counter;

FIG. 29(c) is a diagram showing destinations of the output signals of the four-stage ring counter;

FIG. 29(d) is a diagram showing a configuration example of a switch;

FIG. 30 is a diagram showing a trended variation of output currents in an IC chip in a circuit in which switching control is not performed;

FIG. 31 is a diagram showing how the trended variation of output currents in the IC chip is reduced by switching control;

FIG. 32 is a timing chart which takes into consideration random current variation in DAC portions;

FIG. 33 is a block diagram showing a sixth embodiment of a display panel drive circuit according to the present invention;

FIG. 34 is a diagram showing a configuration example of the switches which compose the switching circuit shown in FIG. 33;

FIG. 35 is a timing chart showing a clock, ON/OFF states of the switches which compose the switching circuit, and control signals;

FIG. 36 is a diagram showing a configuration example of a circuit which generates control signals to be supplied to a gate terminal of a MOSTr shown in FIG. 33; and

FIG. 37 is a timing chart showing ON/OFF states of switches vs. output currents.

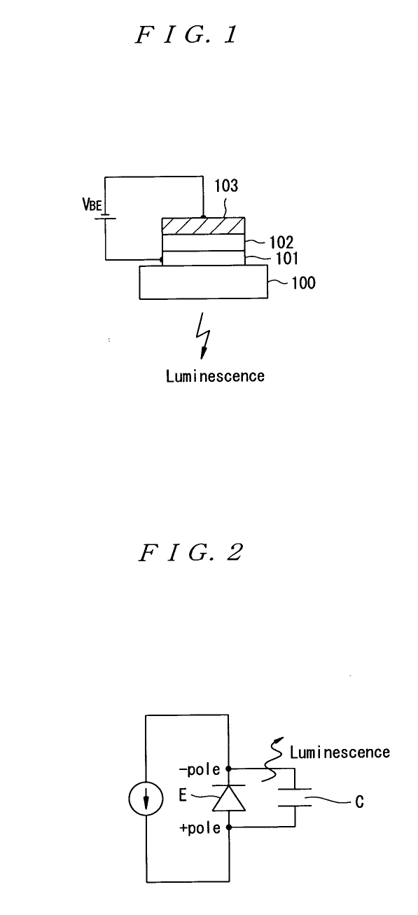

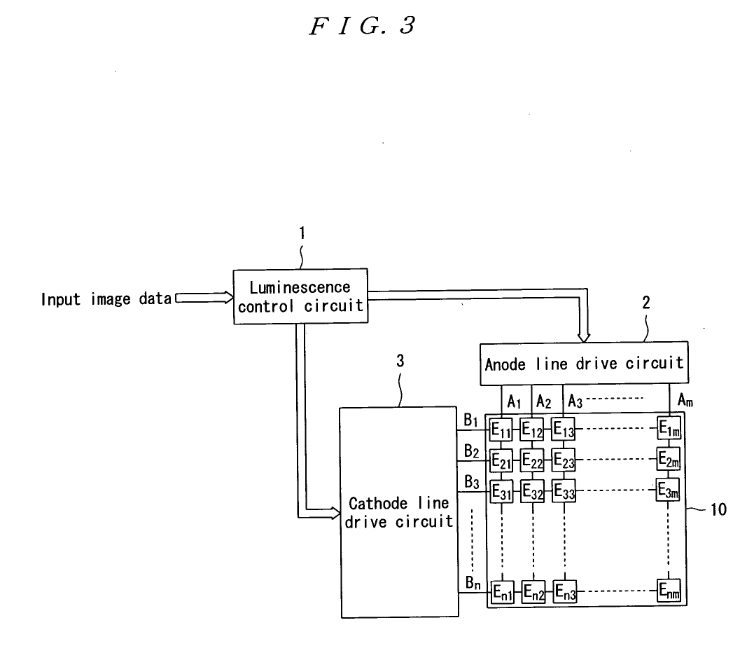

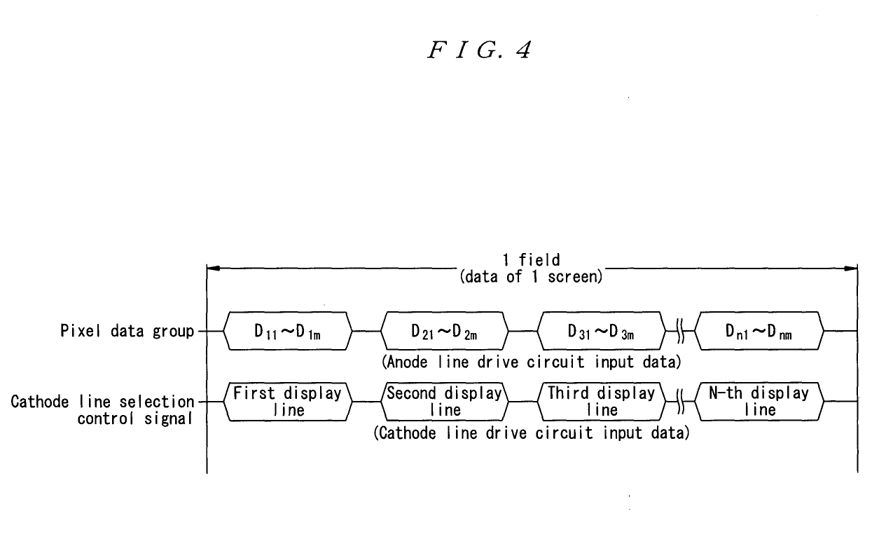

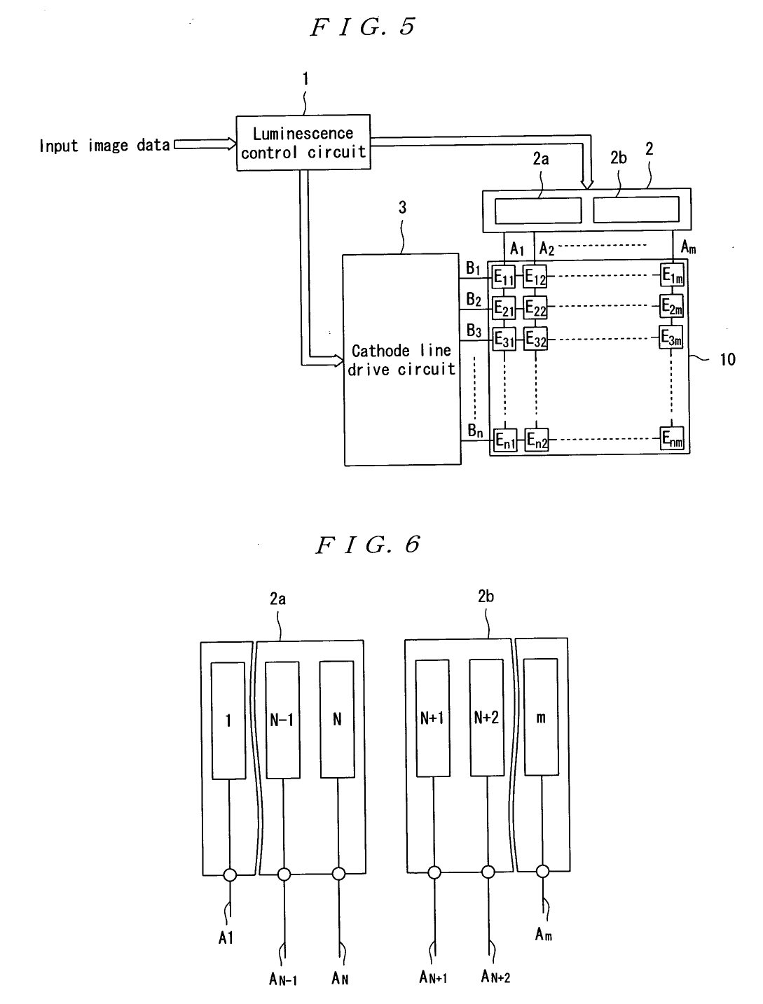

### BEST MODE FOR CARRYING OUT THE INVENTION

Next, embodiments of the present invention will be described with reference to the drawings. In the following description, equivalent parts in different drawings are denoted by the same reference numerals/characters.

FIG. 14 is a diagram showing main components of a first embodiment of a display panel drive circuit according to the present invention. As shown in the figure, the display panel drive circuit according to this embodiment comprises a first IC chip 2a and second IC chip 2b.

The first IC chip 2a has drive outputs corresponding to channel numbers 1 to N+1. Drive outputs corresponding to channel numbers 1 to N−1 are supplied to anode lines A₁ to A_{N-1} to drive pixel elements which correspond to the anode lines A₁ to A_{N-1}.

On the other hand, the second IC chip 2b has drive outputs corresponding to channel numbers N to m. Drive outputs corresponding to channel numbers N+2 to m are supplied to anode lines A_{N+2} to Aₘ to drive pixel elements which correspond to the anode lines A_{N+2} to Aₘ.

In addition to the drive output corresponding to channel number N on the first IC chip 2a, the drive output corresponding to channel number N on the second IC chip 2b is fed into a switching circuit SW1 of the first IC chip 2a. The switching circuit SW1 switches between the two drive outputs and supplies them one at a time to the anode line A_{N}.

Specifically, the switching circuit SW1 receives the drive output corresponding to channel number N which belongs to a drive output group (channel numbers 1 to N+1) of the first IC chip 2a and the drive output corresponding to channel number N which belongs to a drive output group (channel numbers N to m) of the second IC chip 2b, and supplies the two drive outputs one at a time to the anode line A_{N} which belongs to the anode lines A₁ to A_{N} of the first drive line group and adjoins the anode lines A_{N} to Aₘ of the second drive line group by switching between them in predetermined cycles. The drive output corresponding to channel number N on the second IC chip 2b is a dummy drive output d2 which does not correspond to any of the anode lines A_{N} to Aₘ (drive lines) of the second drive line group.

Similarly, the drive output corresponding to channel number N+1 on the first IC chip 2b as well as the drive output corresponding to channel number N+1 on the second IC chip 2a are inputted in a switching circuit SW2 of the second IC chip 2b. The switching circuit SW2 switches between the two drive outputs and supplies them one at a time to the anode line A_{N+1}.

Specifically, the switching circuit SW2 receives the drive output corresponding to channel number N+1 which belongs to a drive output group (channel numbers N to m) of the second IC chip 2b and the drive output corresponding to channel number N+1 which belongs to a drive output group (channel numbers 1 to N+1) of the first IC chip 2a, and supplies the two drive outputs one at a time to the anode line A_{N+1} which belongs to the anode lines A_{N} to Aₘ of the second drive line group and adjoins the anode lines A₁ to A_{N} of the first drive line group by switching between them in predetermined cycles. The drive output corresponding to channel number N+1 on the first IC chip 2a is a dummy drive output d1 which does not correspond to any of the anode lines A₁ to A_{N} (drive lines) of the first drive line group.

Thus, the switching circuits SW1 and SW2 receive dummy drive output from the adjoining IC chip as well as drive outputs within their respective IC chips, supply the two drive outputs to the appropriate anode line in predetermined cycles by switching between them, and thereby perform time-division control. Each of the IC chips 2a and 2b are equipped with a dummy output at an end. The dummy output from the first IC chip 2a is fed into the second IC chip 2b while the dummy output from the second IC chip 2b is fed into the first IC chip 2a.

Incidentally, since the switching circuits SW1 and SW2 are formed in the IC chips 2a and 2b, all that is necessary is to add wirings S1 and S2, and there is no need to provide additional mounting space.

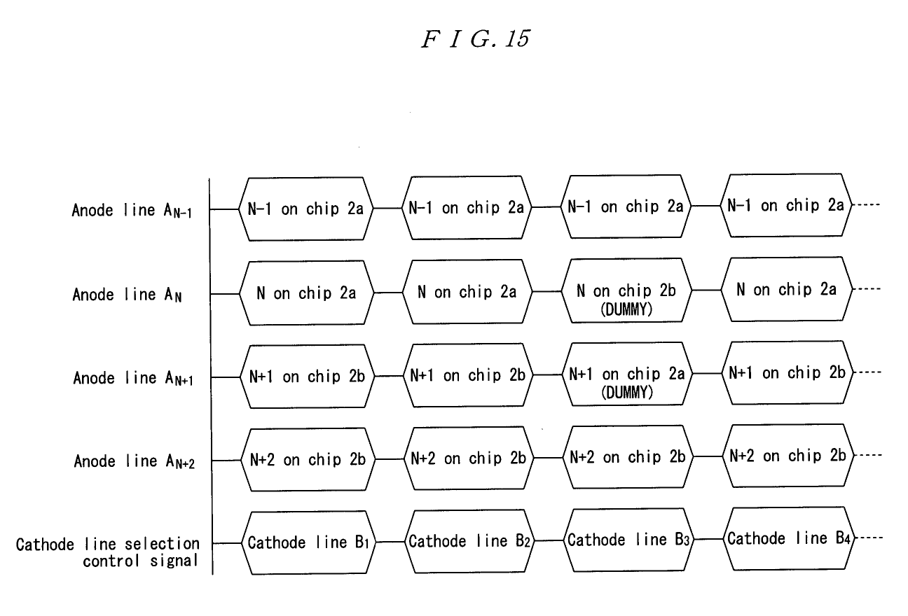

FIG. 15 is an exemplary timing chart showing the timing of drive switching made by the display panel drive circuit. The figure shows an example in which the ratio between the drive output from the first IC chip 2a and drive output from the second IC chip 2b (hereinafter referred to as a switching ratio), supplied to the anode line AN, is 2:1.

When cathode lines B₁, B₂, B₃, and B₄ are selected in sequence by a cathode line selection control signal shown in FIG. 15, the drive output of the IC chip 2a or 2b is supplied to the anode lines. The anode line A_{N-1} is supplied with the drive output from channel number N−1 on the first IC chip 2a while the anode line A_{N+2} is supplied with the drive output from channel number N+2 on the second IC chip 2b.

The anode line A_{N} is supplied with the drive output from channel number N on the first IC chip 2a and the drive output (dummy drive output) from channel number N on the second IC chip 2b one at a time, with the two outputs switched in predetermined cycles. In this example, two successive drive outputs from channel number N on the first IC chip 2a alternate with one drive output from channel number N on the second IC chip 2b. In short, the switching ratio between the first IC chip 2a and second IC chip 2b is 2 to 1.

The anode line A_{N+1} is supplied with the drive output from channel number N+1 on the second IC chip 2b and the drive output (dummy drive output) from channel number N+1 on the first IC chip 2a one at a time, with the two outputs switched in predetermined cycles. In this example, two successive drive output from channel number N on the second IC chip 2b alternate with one drive output from channel number N on the first IC chip 2a. In short, the switching ratio between the first IC chip 2a and second IC chip 2b is 1 to 2.

However, switching cycles are not limited to those shown in FIG. 15, and cycles according to another switching ratio may also be used.

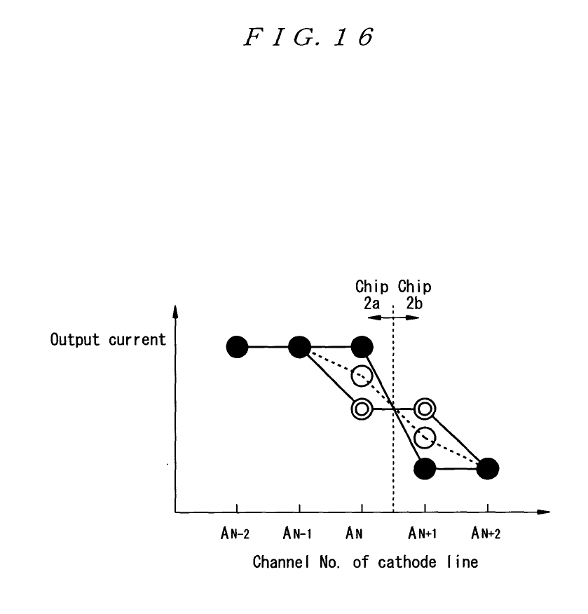

Now, relationship between channel numbers of anode lines and output current will be described with reference to FIG. 16. The figure depicts three cases: the switching ratio in a switching circuit is 1:1, the switching ratio is 2:1, and no switching is made. The solid line linking the black circles ● represents the case in which no switching is made. In this case, the output current from the channel of the anode line A_{N} and the output current from the channel of the anode line A_{N+1} differ greatly. Such a luminance difference impairs image quality.

On the other hand, the solid line linking the double circles ⊚ represents the case in which the switching ratio is 1:1. In this case, there is little difference between the output current from the channel of the anode line A_{N} and the output current from the channel of the anode line A_{N+1}. The difference between the output current from the channel of the anode line A_{N+1} and the output current from the channel of the anode line A_{N+2} as well as the difference between the output current from the anode line A_{N-1} and the output current from the anode line A_{N} in this case are smaller than the difference between the output current from the anode line A_{N} and the output current from the anode line A_{N+1} when no switching is made.

The broken line linking the white circles ◯ represents the case in which the switching ratio is 2:1. In this case, the output current changes gently from the channel of the anode line A_{N-1} through the channel of the anode line A_{N} and the channel of the anode line A_{N+1} to the channel of the anode line A_{N+2}. Thus, luminance difference is smaller than when the switching ratio is 1:1.

If an anode line drive circuit 2 is constructed from a plurality of IC chips, manufacturing variations and the like will cause differences among IC chips in the value of the light emission drive current to be supplied to the anode lines, resulting in screen areas with different luminance. Even in such a case, by switching between the drive outputs of the IC chips in predetermined cycles and supplying them to the drive lines around the boundary of two drive line groups, it is possible to smooth out luminance changes around the boundary between areas with different luminance and prevent image quality from being impaired.

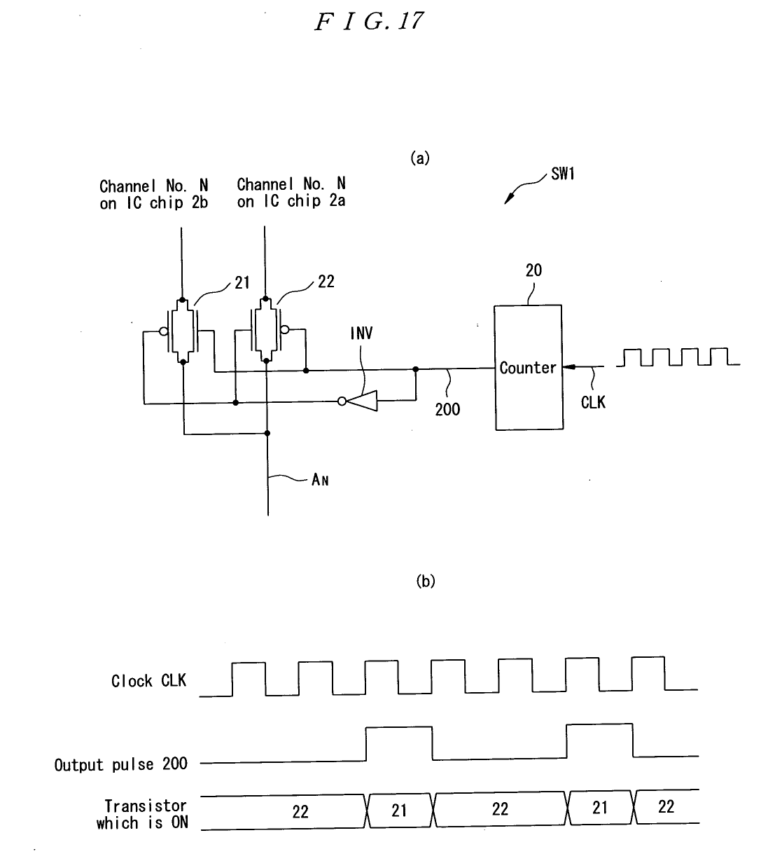

A configuration example of the switching circuit SW1 for the anode line A_{N} is shown in FIG. 17. The switching circuit SW1 shown in the figure comprises two analog switches 21 and 22 which are fed current from channel number N on respective IC chips. Each of the analog switches 21 and 22 consists of an n-channel MOS transistor and p-channel MOS transistor which share both the source and drain. The gates of the n-channel MOS transistor and p-channel MOS transistor serve as switching control terminals, which are turned on and off by mutually inverse signals.

The configuration in FIG. 17 includes a counter 20 which supplies an output pulse 200 to the gates serving as the switching control terminals, and an inverter INV which inverts the output pulse 200. The inverter INV consists, for example, of a known CMOS (Complementary Metal Oxide Semiconductor) inverter circuit.

The n-channel MOS transistor of the analog switch 21 and p-channel MOS transistor of the analog switch 22 are fed the output pulse 200 of the counter 20 as it is while the p-channel MOS transistor of the analog switch 21 and n-channel MOS transistor of the analog switch 22 are fed the output pulse 200 logically inverted by the inverter INV. Thus, when the output pulse 200 of the counter 20 is High, the analog switch 21 is ON and the analog switch 22 is OFF. On the other hand, when the output pulse 200 of the counter 20 is Low, the analog switch 21 is OFF and the analog switch 22 is ON.

The counter 20 is fed a clock CLK which is in synchronization with the cathode line selection control signals (see FIG. 15). The clock CLK does counting, generating the output pulse 200 with a duty ratio which corresponds to the ratio described above. The ON/OFF states of the analog switches 21 and 22 are controlled by the output pulse 200 so that only one of the analog switches 21 and 22 will be ON at a time.

Specifically, as shown in FIG. 17(b), when the counter 20 which is fed the clock CLK supplies the output pulse 200 to the analog switches 21 and 22, the ratio between the duration for which the analog switch 22 is ON and duration for which the analog switch 21 is ON is 2:1. Consequently, the anode line A_{N} is supplied with the drive output from channel number N on the first IC chip 2a and drive output from channel number N on the second IC chip 2b at a ratio of 2:1. Similarly, the switching circuit SW2 for the anode line A_{N+1} can also be constructed from two analog switches and a counter.

Incidentally, although two IC chips are used in the example described above, the present invention is not limited to this. It is obvious that the present invention also applies to cases in which more than two IC chips are used. In that case as well, dummy drive output not corresponding to any drive line on the IC chip and the proper drive output of the adjoining IC chip can be switched in predetermined cycles and supplied to the drive line as is the case with the above example. This can reduce the luminance differences in two display areas caused by differences in current driving capacity among IC chips and reduce degradation of image quality.

Also, although one dummy drive output is provided in each of the adjoining IC chips in the example described above, the present invention is not limited to this. It is obvious that the present invention also applies to cases in which two or more dummy drive outputs are provided in each IC chip. A plurality of dummy drive output corresponding each drive line on the IC chip and a plurality of proper drive outputs of the adjoining IC chip can be switched in predetermined cycles and supplied to the drive line as is the case with the above example. By varying the switching ratio among the drive outputs, it is possible to further reduce the luminance differences in two display areas caused by differences in current driving capacity among IC chips and reduce degradation of image quality.

Also, although the pixel elements composing the display panel are EL elements in the example described above, it is obvious that the present invention also applies to cases in which other elements are used.

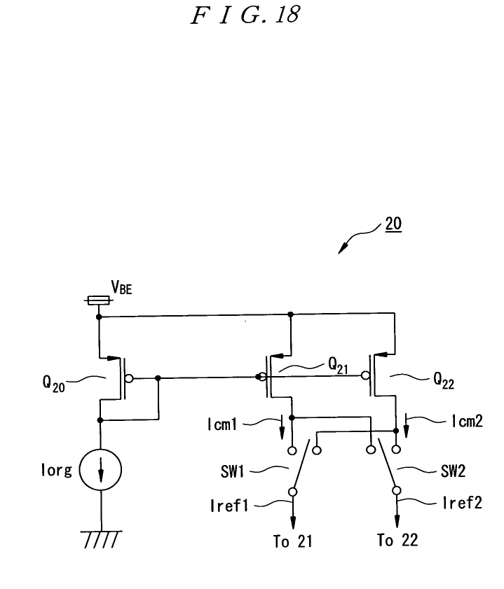

FIG. 18 is a diagram showing main components of a second embodiment of a display panel drive circuit according to the present invention. The figure shows a reference current generating circuit. In this example, reference current is supplied to two IC chips.

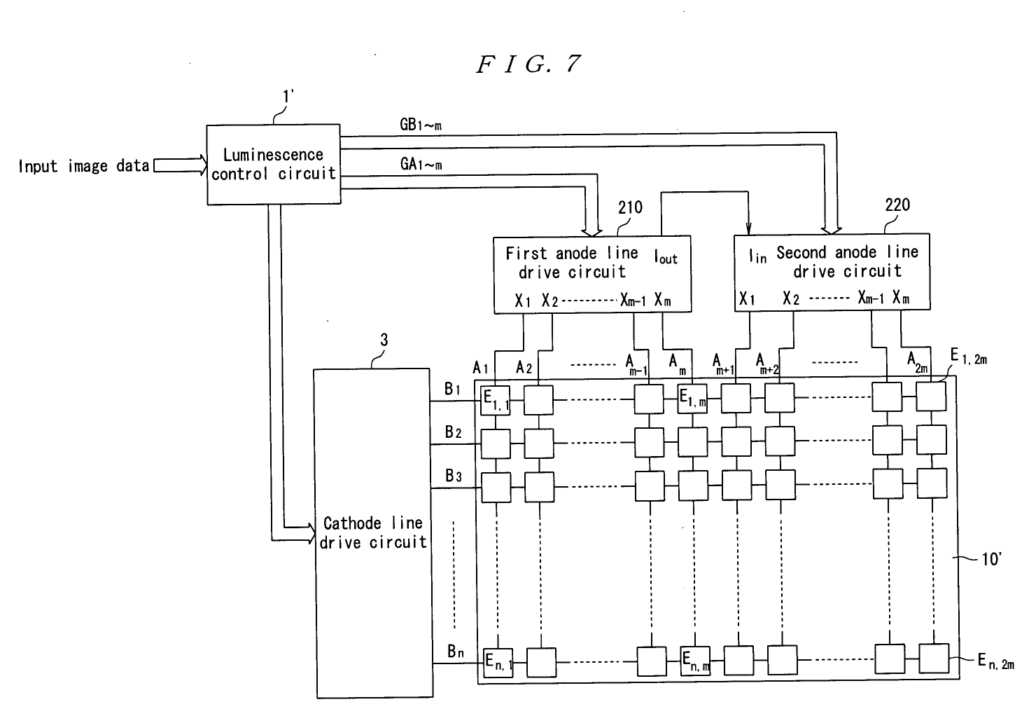

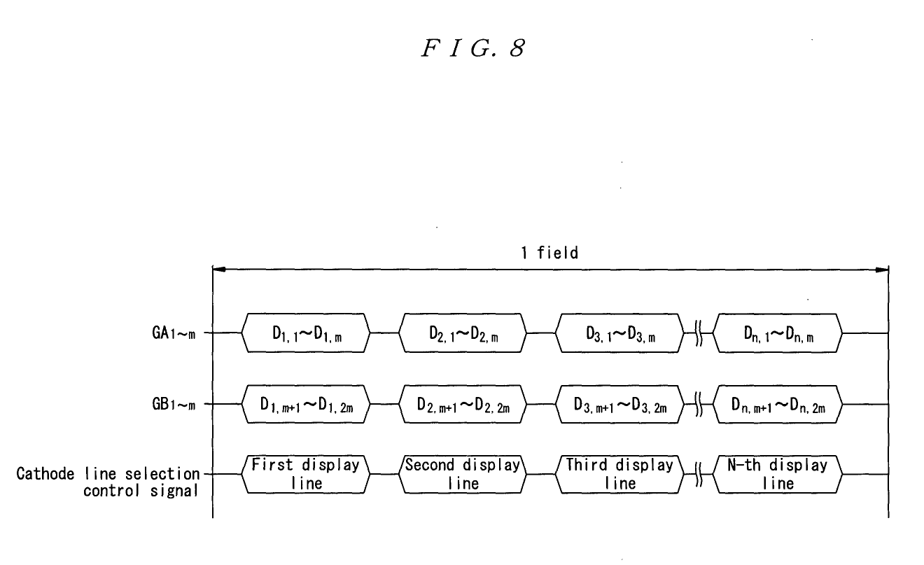

As shown in the figure, the reference current generating circuit 20 comprises a current source I_{org}, a transistor Q₂₀ which compose a reference current source in conjunction with the current source I_{org}, and transistors Q₂₁ and Q₂₂ which use the current source I_{org} and transistor Q₂₀ as a common reference current source and compose a current mirror in conjunction with the reference current source. Currents I_{cm1} and I_{cm2} derived from the transistors Q₂₁ and Q₂₂ are supplied to cathode line drive circuits 210 and 220 consisting of IC ships (see FIG. 7).

Furthermore, the reference current generating circuit 20 comprises switching circuits SW1 and SW2 which switch correspondence between the currents I_{cm1} and I_{cm2} derived from the transistors Q₂₁ and Q₂₂, and the cathode line drive circuits 210 and 220 in predetermined cycles. To put it in another way, the currents I_{cm1} and I_{cm2} derived from the transistors Q₂₁ and Q₂₂ are switched by the switching circuits SW1 and SW2, and supplied as output currents I_{ref1} and I_{ref2} to drive circuits 21 and 22 not shown.

Time-division control by means of the switching circuits SW1 and SW2 reduces the amounts of variation between the current source I_{org} which provides the source current of the current mirror and currents I_{ref1} and I_{ref2}, and equalizes the current I_{ref1} and current I_{ref2}. Specifically, if the amount of variation between the source current I_{org} of the current mirror and the current I_{cm1} generated by the current mirror is ΔI₁ and the amount of variation between the source current I_{org} of the current mirror and the current I_{cm2} generated by the current mirror is ΔI ₂, since variations in the output currents I_{ref1} and I_{ref2} of the switching circuits are also time-divided, the average variation is as follows:

Average variation=1/2×√(ΔI₁²+ΔI₂²)

If it is assumed that ΔI₁ and ΔI₂ are equal to ΔI,

Average variation=1√\vec{}2×ΔI

This is smaller than the amounts of variation in the currents I_{cm1} and I_{cm2} generated by the current mirror.

Also, since the output currents I_{ref1} and I_{ref2} of the switching circuits are equal, variation in output current among IC chips can be reduced even when a plurality of IC chips are used.

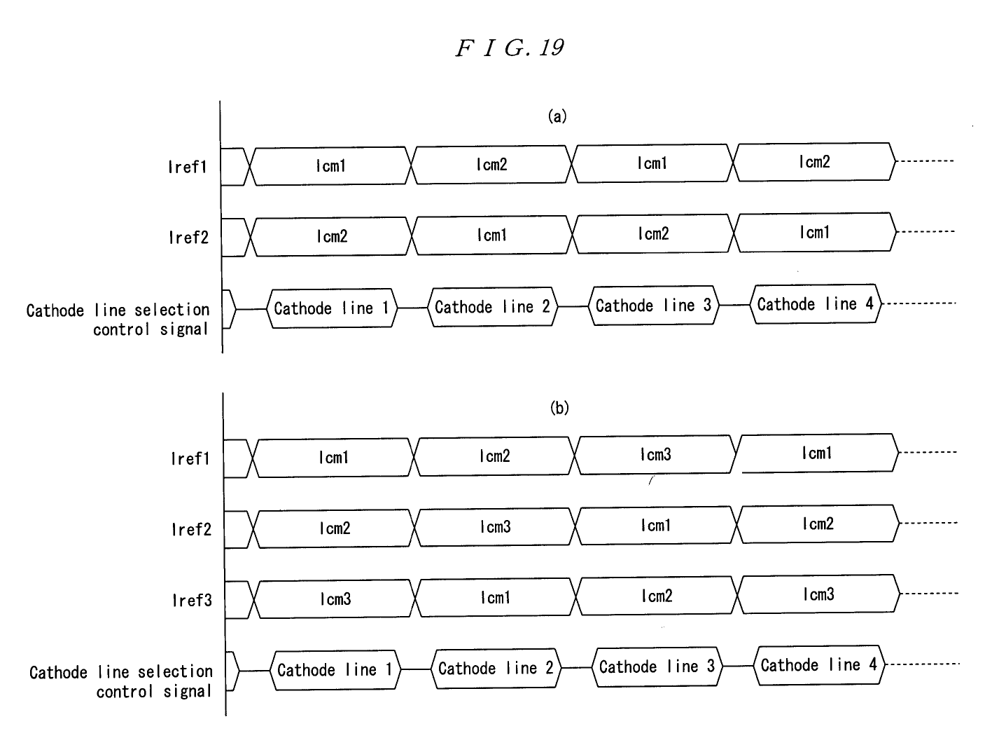

Switching circuits are operated in synchronization with switching of a cathode line signal. FIG. 19(a) is a timing chart showing switch timing of switching circuits. The figure shows how the current I_{cm1} and current I_{cm2} generated by the current mirror are output as the output currents I_{ref1} and I_{ref2} through the operation of the switching circuits SW1 and SW2.

As shown in FIG. 19(a), by operating the switching circuits at the time when cathode lines 1, 2, 3, . . . are off, it is possible to reduce switching noise produced when switching between the current I_{ref1} and current I_{ref2}. This in turn makes it possible to realize a good image display by avoiding screen flicker and other adverse effects.

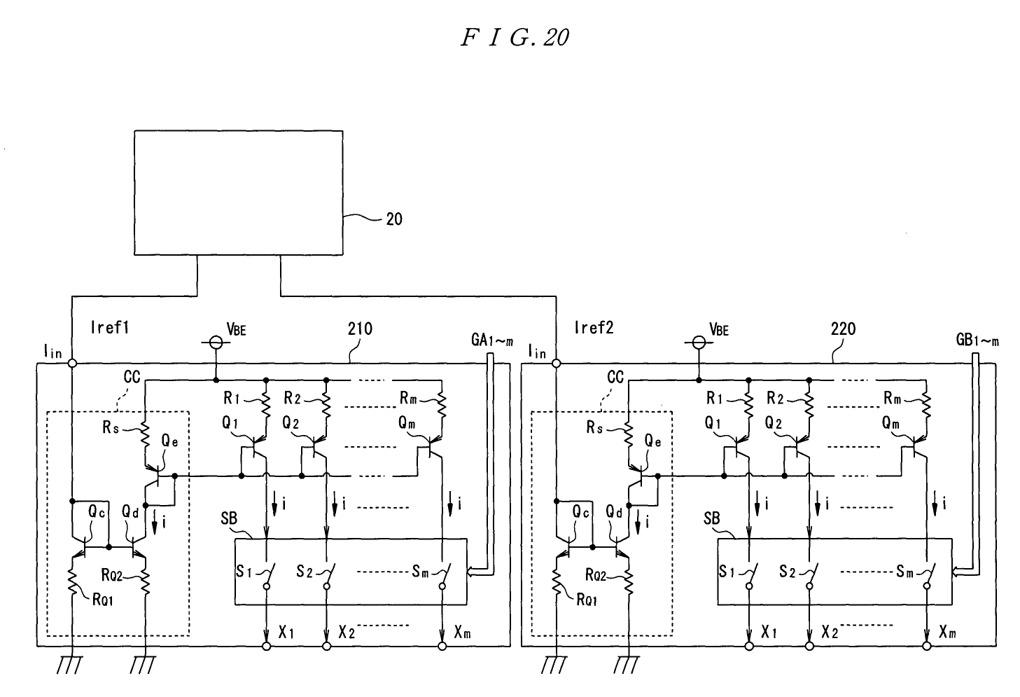

FIG. 20 shows how the reference current generating circuit 20 is connected with the first anode line drive circuit 210 and second anode line drive circuit 220. Referring to the figure, the output current I_{ref1} produced through the switching operations of the switching circuits SW1 and SW2 are fed into the first anode line drive circuit 210 as the reference current for the current mirror while the output current I_{ref2} is fed into the second anode line drive circuit 220 as the reference current for the current mirror.

Since the output current I_{ref1} and output current I_{ref2} from the switching circuits of the reference current generating circuit 20 described above are equal to each other, it is possible to reduce variation in the currents supplied, respectively, to the first anode line drive circuit 210 and second anode line drive circuit 220 constructed from different IC chips.

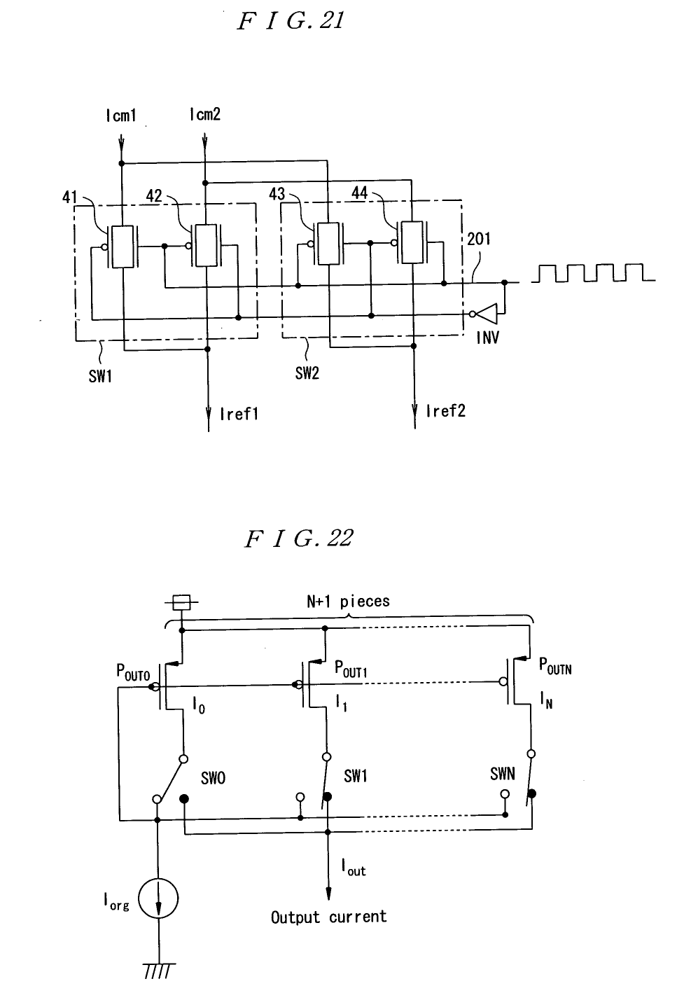

FIG. 21 shows a configuration example of switching circuits SW1 and SW2. Both switching circuits SW1 and SW2 in the figure are constructed from MOS transistors, etc.

The switching circuits SW1 and SW2 shown in FIG. 21 comprises two analog switches 41 and 42 or analog switches 43 and 44, which are fed current outputted from channel number N on respective IC chips. Each of the analog switches 41, 42, 43, and 44 consists of an n-channel MOS transistor and p-channel MOS transistor which share both the source and drain. The gates of the n-channel MOS transistor and p-channel MOS transistor serve as switching control terminals, which are turned on and off by mutually inverse signals.

The configuration in FIG. 17 includes an inverter INV which supplies an inverted pulse 201 to the gates serving as the switching control terminals. The inverter INV consists, for example, of a known CMOS inverter circuit.

The n-channel MOS transistor of the analog switch 41, p-channel MOS transistor of the analog switch 42, p-channel MOS transistor of the analog switch 43, and n-channel MOS transistor of the analog switch 44 are fed the pulse 201 as it is while the p-channel MOS transistor of the analog switch 41, n-channel MOS transistor of the analog switch 42, n-channel MOS transistor of the analog switch 43, and p-channel MOS transistor of the analog switch 44 are fed the output pulse 201 logically inverted by the inverter INV. Thus, when the pulse 201 is High, the analog switches 41 and 44 are ON and the analog switches 42 and 43 are OFF. On the other hand, when the pulse 201 is Low, the analog switches 41 and 44 are OFF and the analog switches 42 and 43 are ON.

During the former period, the current I_{cm1} is derived as the output current I_{ref1} and the current I_{cm2} is derived as the output current I_{ref2}. On the other hand, during the latter period, the current I_{cm1} is derived as the output current I_{ref2} and the current I_{cm2} is derived as the output current I_{ref1}. By configuring the switching circuits in the manner described above, it is possible to reduce variation in output current among IC chips even when a plurality of IC chips are used.

Incidentally, although in the embodiment described above, the reference current generating circuit 20 is installed outside the cathode line drive circuits 210 and 220 each constructed from an IC chip, it is also possible to install the reference current generating circuit 20 in the IC chips and supply the output current I_{ref1} to one of the IC chips, and the output current I_{ref2} to the other IC chip. In that case, the display panel drive circuit can be constructed from only two IC chips with one of the IC chips serving as a master IC and the other IC chip serving as a slave IC.

Also, although two IC chips are used in the example described above, even if more than two IC chips are used, by switching correspondence (electrical connection) between the IC chips and drive current supply sources in predetermined cycles, it is possible to reduce variation in output current among IC chips.

For example, if a plurality of drive current sources are provided for a plurality of IC chips and connection between the IC chips and drive current sources is switched in rotation in predetermined cycles, the drive currents of the IC chips can be averaged and almost equalized. FIG. 19(b) is a timing chart showing the timing to switch among three drive current sources in rotation among three IC chips.

FIG. 22 is a diagram showing main components of a third embodiment of a display panel drive circuit according to the present invention. The figure shows a current mirror circuit composed of N+1 MOS transistors.

As shown in FIG. 22, the current mirror circuit comprises a current source I_{org}, the N+1 MOS transistors P _{OUT0}, P_{OUT1}, . . . , and P_{OUTN}, and switching circuits SW0, SW1, . . . , and SWN. The switching circuits SW0, SW1, . . . , and SWN electrically connects only one of the N+1 MOS transistors P_{OUT0}, P_{OUT1}, . . . , and P_{OUTN} to the current source I_{org}. The MOS transistor connected to the current source I_{org} serves as a reference current source for the current mirror in conjunction with the current source I_{org}. The output currents from the other N MOS transistors are used as drive output for the display panel. In this example, the outputs from the N MOS transistors P_{OUT1} to P_{OUTN} are merged into an output current Iₒᵤₜ, which is derived as a drive output.

In FIG. 22, in relation to the switching circuits SW0, SW1, . . . , and SWN, terminals connected to the current source I_{org} are indicated by ◯ while terminals connected to a signal line which derives the output current Iₒᵤₜ are indicated by ●. When the switching circuit SW0 is connected to the ◯ terminal, the other switching circuits SW1 to SWN are connected to the respective terminals. When the switching circuit SW1 is connected to the ◯ terminal, the switching circuits SW0 and SW2 to SWN are connected to the respective terminals. In this way, the switching circuit connected to the ◯ terminal is changed in sequence. This switching is made in synchronization with a clock.

As the switching circuits SW0, SW1, . . . , and SWN are operated in this way, the transistor which serves as a reference current source is switched periodically from among the N+1 MOS transistors P_{OUT0}, P_{OUT1}, P_{OUT2}, and P_{OUTN}. Specifically, through the operation of the switching circuits, each of the N+1 MOS transistors is set to the first proportional “1” of a current ratio 1:N in sequence so as to have a major current variation. Through this switching control, current variation among all the N+1 MOS transistors is controlled in a time-divided manner. In short, they are controlled in such a way as to be averaged over time. This suppresses current variation.

Suppose the number of transistors N=3 and the variation among transistors is 1%. Whereas conventionally current variation is around 1.4%, with the circuit according to the present invention, current variation is around 0.01%. Thus, the current variation is reduced considerably.

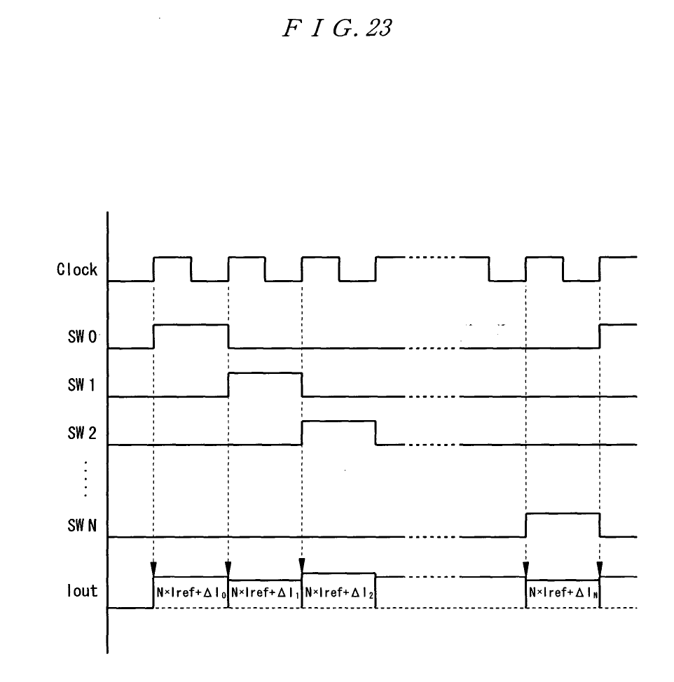

FIG. 23 is a timing chart showing switch timing of the switching circuits SW0 to SWN. The figure shows a clock which provides the timing for switching the switching circuits, ON/OFF states of the switching circuits, and the output current Iₒᵤₜ. Incidentally, in the figure, the switching circuits are ON when they are High.

In FIG. 23, when the switching circuit SW0 is ON, the output current Iₒᵤₜ is N×I_{ref}+ΔI₀. Similarly, when the switching circuit SW1 is ON, the output current Iₒᵤₜ is N×I_{ref}+ΔI₁; when the switching circuit SW2 is ON, the output current Iₒᵤₜ is N×I_{ref}+ΔI₂; and when the switching circuit SWN is ON, the output current Iₒᵤₜ is N×I_{ref}+ΔI_{N}. In this way, the transistor which serves as the reference current source is changed periodically by the switching circuits.

As described above, by periodically changing the transistor which serves as the reference current source, it is possible to reduce the amount of current variation.

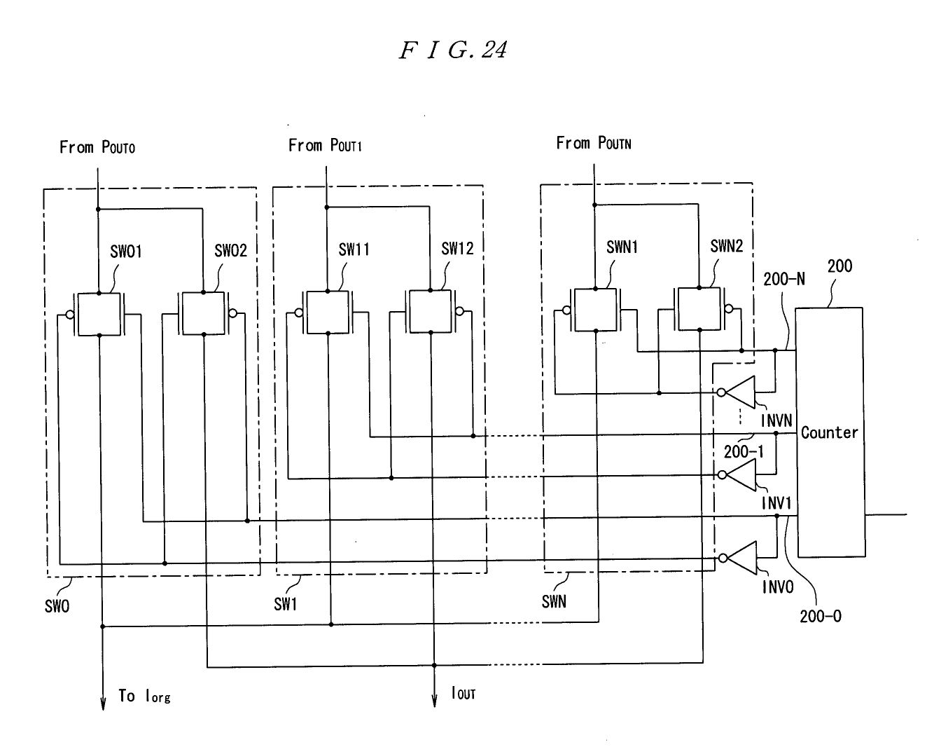

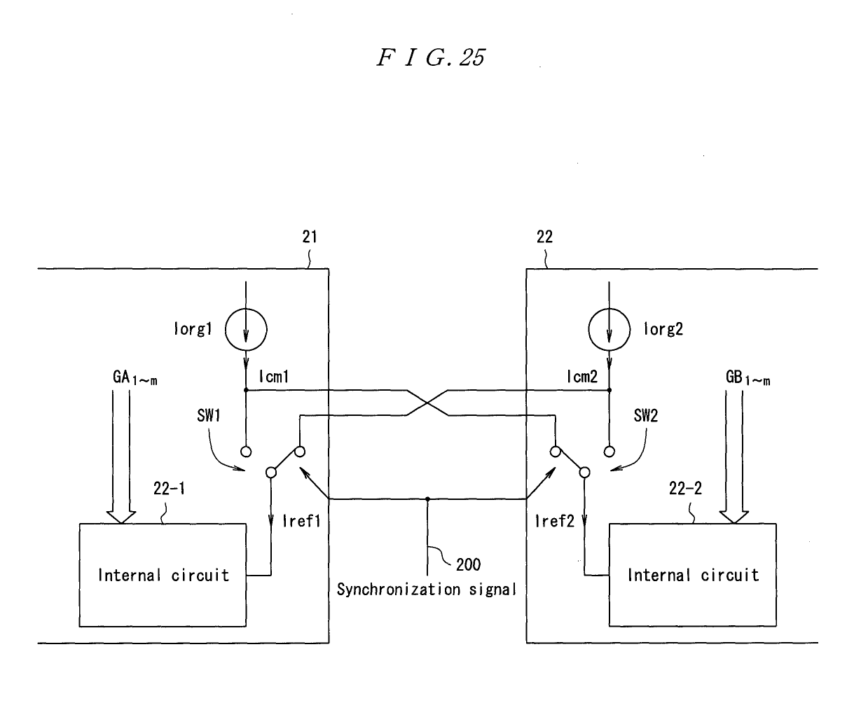

FIG. 24 shows a configuration example of the switching circuits shown in FIG. 22. Each of the switching circuits SW0 to SWN in FIG. 24 comprises two analog switches and is fed current outputted from the corresponding one of the MOS transistors P_{OUT0} to P_{OUTN}. The switching circuit SW0 comprises analog switches SW01 and SW02. Each of the analog switches SW01 and SW02 consists of an n-channel MOS transistor and p-channel MOS transistor which share both the source and drain. The common gate of the n-channel MOS transistor and p-channel MOS transistor serves as a switching control terminal. The configuration in FIG. 24 includes a counter 200 which is fed the clock described above, and inverters INV0 to INVN which are installed for the respective switching circuits SW0 to SWN and invert outputs 200-0 to 200-N of the counter 200. The inverters INV0 to INVN consist, for example, of a known CMOS inverter circuit.

The n-channel MOS transistor of the analog switch SW01 and p-channel MOS transistor of the analog switch SW02 are fed counter 200 output as it is while the p-channel MOS transistor of the analog switch SW01 and n-channel MOS transistor of the analog switch SW02 are fed counter 200 output logically inverted by the inverter INV0. Thus, the analog switch SW01 is ON only when the output 200-0 of the counter 200 is High, and the analog switch SW02 is ON when the output 200-0 of the counter 200 is Low.

Similarly, in the case of the switching circuit SW1 consisting of analog switches SW11 and SW12, the analog switch SW11 is ON only when the output 200-1 of the counter 200 is High, and the analog switch SW12 is ON when the output 200-1 of the counter 200 is Low. The same applies to the other switching circuits: in the switching circuit SWN, the analog switch SWN1 is ON only when the output 200-N of the counter 200 is High, and the analog switch SWN2 is ON when the output 200-N of the counter 200 is Low.

Incidentally, as shown in FIG. 24, the outputs of the analog switches SW01, SW11, . . . , and SWN1 are connected to the current source I_{org} while the outputs of the analog switches SW02, SW12, . . . , and SWN2 are merged into an output current Iₒᵤₜ.

In this configuration, the counter 200 is fed the clock shown in FIG. 23. It sets only one of the outputs 200-1 to 200-N to High in turns. Thus, it shifts the outputs set to High in sequence. By shifting the high pulse among the outputs in this way, it periodically changes the transistor which serves as the reference current source from among the N+1 MOS transistors as shown in FIG. 23. Consequently, each of the N+1 MOS transistors is set to the first proportional “1” of the current ratio 1:N in sequence so as to have a major current variation. Through this switching control, current variation among all the N+1 MOS transistors is controlled in a time-divided manner. This configuration makes it possible to reduce current variation without increasing the amount of the current of the current source I_{org}.

Therefore, this circuit can reduce current variation in the current mirror without increasing power consumption of the IC chips. Thus, as the switching circuits are controlled using a clock with a repetition frequency of, for example, 1000 Hz, the current supplied to a display panel composed of organic electroluminescent elements can be averaged overtime. This produces uniform emission luminance on the display panel.

FIG. 25 is a diagram showing main components of a fourth embodiment of a display panel drive circuit according to the present invention. The figure shows a case in which two IC chips are used.

As shown in FIG. 25, a first anode line drive circuit 210 made of an IC chip contains a current source I_{org1} which outputs a reference current for a current mirror, and a switching circuit SW1 which receives, as one of inputs, a reference current I_{cm1} outputted from the current source I_{org1}. The reference current I_{cm1} is also fed into a switching circuit SW2 in a second anode line drive circuit 220 made of another IC chip.

The second anode line drive circuit 220 contains a current source I_{org2} which outputs a reference current for a current mirror, and the switching circuit SW2 which receives, as one of inputs, a reference current I_{cm2} outputted from the current source I_{org2}. The reference current I_{cm2} is also fed into a switching circuit SW1 in the anode line drive circuit 210.

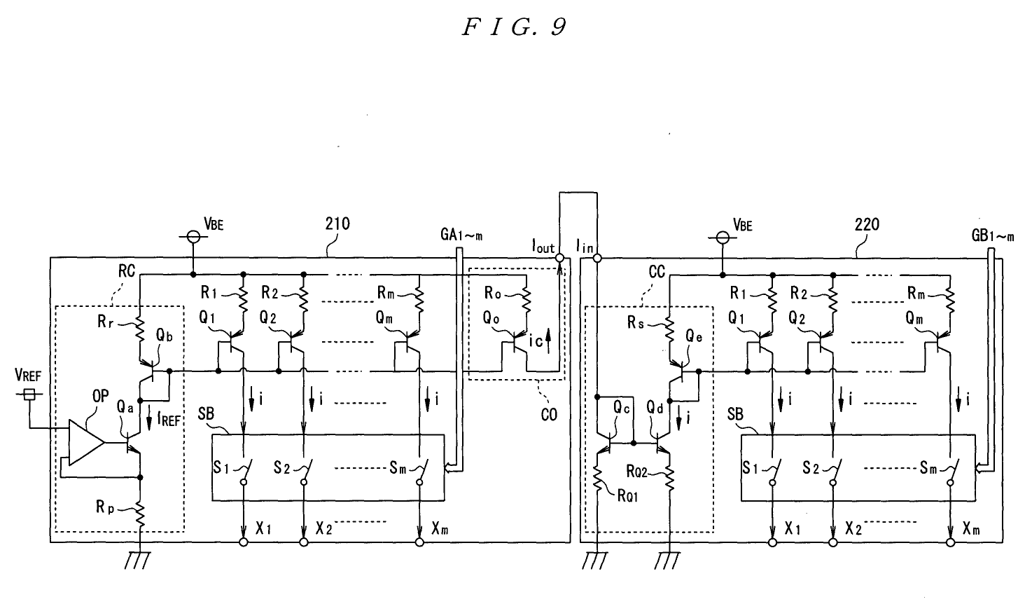

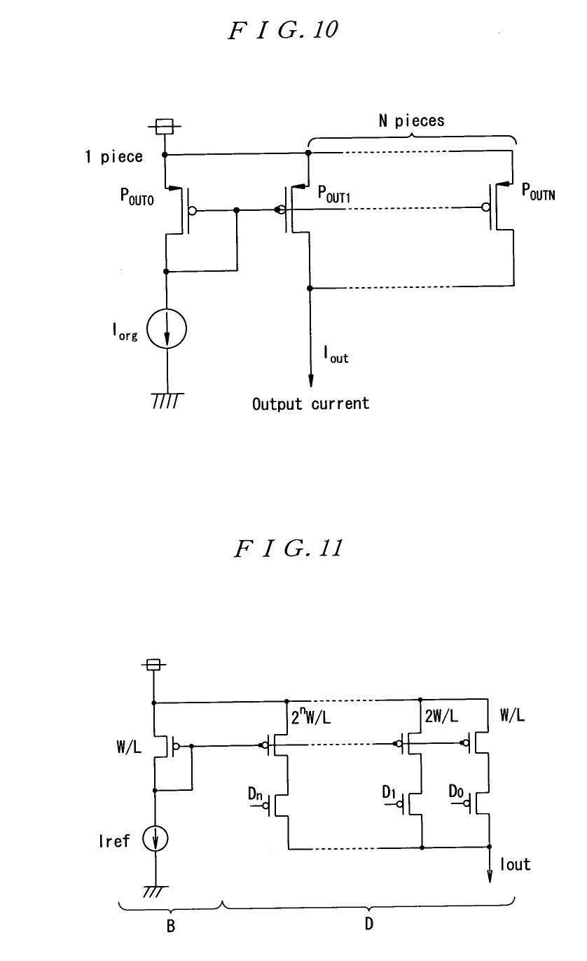

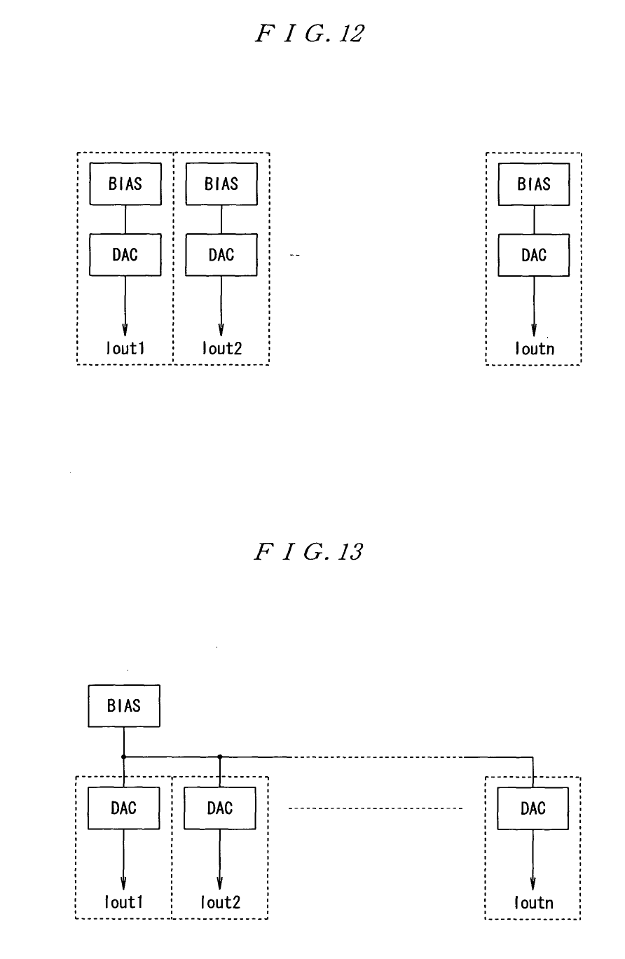

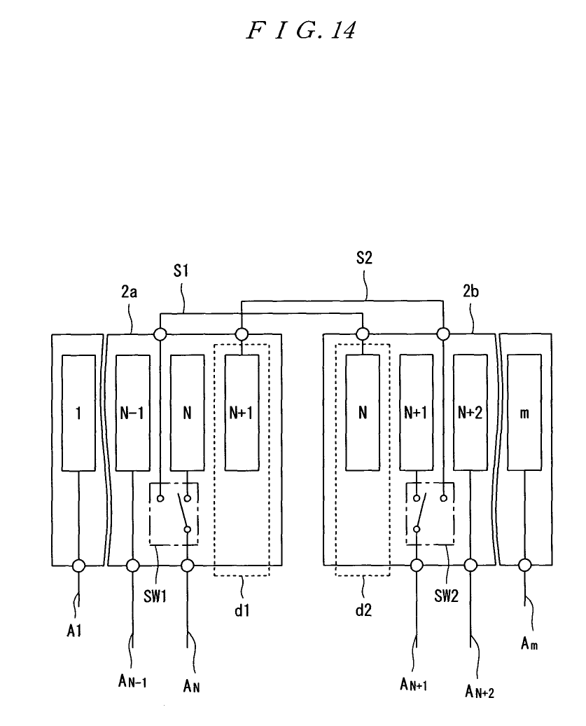

An internal circuit 22-1 in the anode line drive circuit 210 and an internal circuit 22-2 in the second anode line drive circuit 220 have a configuration equivalent to that of the second anode line drive circuit 220 in FIG. 9. Specifically, the internal circuits 22-1 and 22-2 have a current mirror, with which they generate drive current for driving the display panel.

The internal circuit 22-1 is fed a reference current I_{ref1}, which is either the reference current I_{cm1} or I_{cm2} selected by the switching circuit SW1. Similarly, the internal circuit 22-2 is fed a reference current I_{ref2}, which is either the reference current I_{cm1} or I_{cm2} selected by the switching circuit SW2.

The switching circuits SW1 and SW2 are controlled by a synchronization signal 200 synchronized with a scan line selection signal. The switching circuit SW1 and switching circuit SW2 are controlled in such a way as to select different one of the reference currents I_{cm1} and I_{cm2} . Specifically, the switching circuits switch between the output currents from the current source I_{org1} and current source I_{org2} for time-division control based on the synchronization signal 200 from outside. Thus, the output currents are controlled in such a way as to be averaged over time.

Consequently, current is fed into the internal circuits alternately to allow each of the anode line drive circuits 210 and 220 to use averaged current internally. As a result of time-division switching control, the reference current I_{ref1} and reference current I_{ref2} fed into the anode line drive circuits 210 and 220 equal the time-average of the reference current I_{cm1} and reference current I_{cm2} supplied from the current sources I_{org1} and current source I_{org2}. Thus, the reference current I_{ref1} and reference current I_{ref2} become equal to each other. Specifically, by switching the current source I_{org1} and current source I_{org2} of the anode line drive circuits 210 and 220 at a duty ratio of 1/2 (50%), it is possible to obtain averaged current. By driving the display panel using such an averaged current, it is possible to eliminate variation between reference currents, and thus obtain uniform emission luminance on the display panel.

The operation of the switching circuits is similar to the one shown in FIG. 19(a). is a timing chart showing. The figure shows the reference current I_{ref1} fed into the anode line drive circuit 210, reference current I_{ref2} fed into the anode line drive circuit 220, and scan line selection signal. As shown in the figure, the switching circuits SW1 and SW2 are switched, timed with switching of the cathode line. As a result of this switching control, the reference current I_{cm1} outputted from the current source I_{org1} and the reference current I_{cm2} outputted from the current source I_{org2} are fed alternately as the reference current I_{ref1} and reference current I_{ref2} into the anode line drive circuit 210 and the anode line drive circuit 220. Consequently, an averaged current is supplied to the plurality of anode line drive circuits. Thus, even if there are variations among the currents outputted from a plurality of IC chips (anode line drive circuits), each of the IC chips operates on averaged current in the long run, eliminating variation between reference currents. This makes it possible to obtain uniform emission luminance on the display panel.

If the switching control is performed when the cathode line current is OFF, in particular, the noise produced by the switching operation of the reference current I_{ref1} and reference current I_{ref2} can be minimized. This makes it possible to realize a better image display by avoiding screen flicker and other adverse effects.

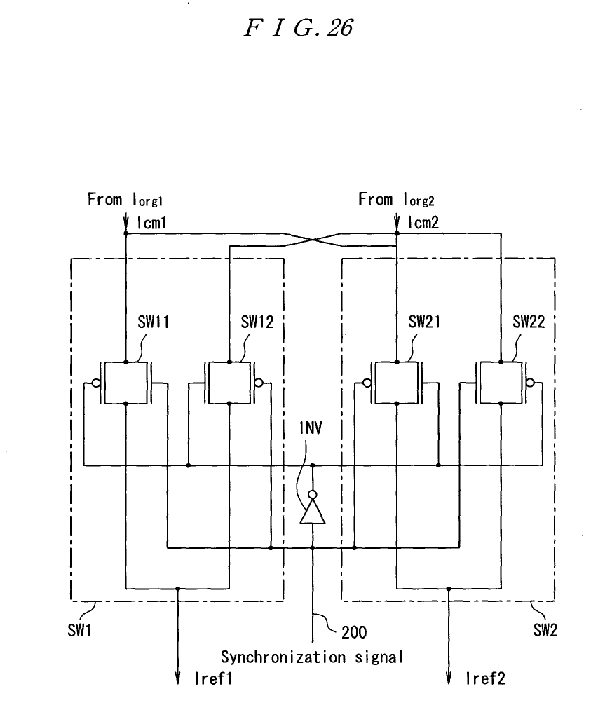

A configuration example of switching circuits is shown in FIG. 26. Each of the switching circuits SW1 and SW2 shown in FIG. 26 comprises two analog switches which are fed the current I_{cm1} and current I_{cm2} outputted from respective reference current sources I_{ref1} and I_{ref2}. The switching circuit SW1 consists of analog switches SW11 and SW12. Each of the analog switches SW11 and SW12 consists of an n-channel MOS transistor and p-channel MOS transistor which share both the source and drain. The gates of the n-channel MOS transistor and p-channel MOS transistor serve as switching control terminals, which are turned on and off by mutually inverse signals. The outputs of the analog switches SW11 and SW12 are merged into the reference current I_{ref1} as described above.

Similarly, the switching circuit SW2 consists of analog switches SW21 and SW22. Each of the analog switches SW21 and SW22 consists of an n-channel MOS transistor and p-channel MOS transistor which share both the source and drain. The gates of the n-channel MOS transistor and p-channel MOS transistor serve as switching control terminals, which are turned on and off by mutually inverse signals. The outputs of the analog switches SW21 and SW22 are merged into the reference current I_{ref2} as described above.

The configuration in the figure includes an inverter INV which inverts the synchronization signal 200 described above. The inverter INV consists, for example, of a known CMOS inverter circuit.

The n-channel MOS transistor of the analog switch 11 and p-channel MOS transistor of the analog switch 12 are fed the synchronization signal 200 as it is while the p-channel MOS transistor of the analog switch 11 and n-channel MOS transistor of the analog switch 12 are fed the synchronization signal 200 logically inverted by the inverter INV. Thus, when the synchronization signal 200 is High, the analog switch 11 is ON and when the synchronization signal 200 is Low, the analog switch 12 is ON.

On the other hand, the p-channel MOS transistor of the analog switch 21 and n-channel MOS transistor of the analog switch 22 are fed the synchronization signal 200 as it is while the n-channel MOS transistor of the analog switch 21 and p-channel MOS transistor of the analog switch 22 are fed the synchronization signal 200 logically inverted by the inverter INV. Thus, when the synchronization signal 200 is High, the analog switch 22 is ON and when the synchronization signal 200 is Low, the analog switch 21 is ON.

With this configuration, when the synchronization signal 200 is High, the analog switches SW11 and SW22 are ON. In this state, the current I_{cn1} and current I_{cm2} are outputted as the current I_{ref1} and current I_{ref2}, respectively. On the other hand, when the synchronization signal 200 is Low, the analog switches SW12 and SW21 are ON. In this state, the current I_{cm1} and current I_{cm2} are outputted as the current I_{ref2} and current I_{ref1}, respectively.

Therefore, if the duty ratio of the synchronization signal 200 is set to 1/2 (50%), the current I_{cm1} and current I_{cm2} are averaged and outputted as the current I_{ref1} and current I_{ref2}. Thus, even if there are variations among the currents outputted from a plurality of IC chips, each of the IC chips operates on averaged current in the long run, eliminating variation between reference currents. This makes it possible to obtain uniform emission luminance on the display panel.

The prior art technology shown in FIG. 9 is configured to deliver the same current from one master IC chip (internal current source) to slave IC chips (see FIG. 9). In this conventional configuration, the current variation of the product as a whole depends on the reference current of the master current source. When the variation in the master current is +/−10%, even if the current is delivered to the slaves without error, the overall variation of 10% is not improved. However, according to this embodiment, which changes the IC ship serving as the current source in sequence, even if each current source has a variation of 10%, the variations are averaged and the current variation of the product as a whole is reduced to 10/√N, which is less than 10%. In other words, whereas the variation in the display luminance of an organic EL panel depends on the variation in the master reference current in the case of the prior art technology, according to the present invention, the variations among the current sources in the IC chips are averaged, and thus the luminance variation of the panel product is improved.

Incidentally, although two IC chips are used in the example described above, even if more than two IC chips are used, similar effects can be obtained by switching among currents in a similar manner. For example, when using three IC chips, the currents supplied to the IC chips can be averaged out if the analog switch shown in FIG. 26 is added to each IC chip and switching control is performed in each IC chip using a synchronization signal with a pulse duty ratio of 1/3 (approximately 33%). Specifically, if the number of IC chips is N, the electrical contact between reference current sources and IC chips can be switched using pulses with a duty ratio of 1/3.

As described above, by switching the correspondence (electrical contact) between reference current sources and IC chips in predetermined cycles, it is possible to average out the currents supplied to the IC chips and reduce variation in output current among IC chips.

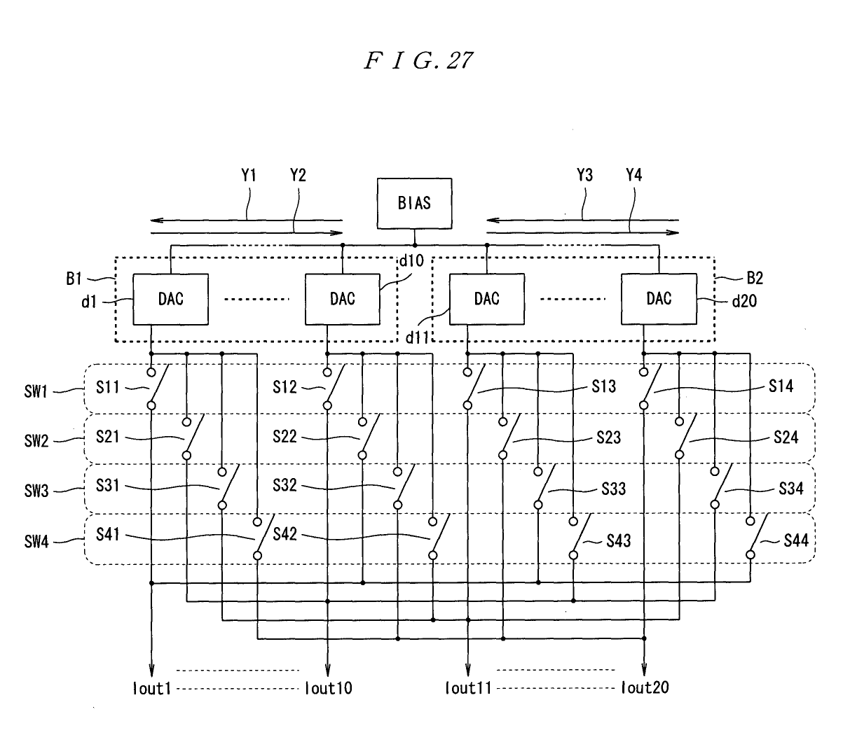

FIG. 27 is a block diagram showing main components of a fifth embodiment of a display panel drive circuit according to the present invention. The figure shows a display panel drive circuit which consists of a single BIAS portion and a plurality of DAC portions. The circuit solves problems with conventional circuits by interchanging the output currents from the DAC portions on individual channels among the channels in sequence.

The figure shows a circuit configuration in which the plurality of DAC portions are divided into two blocks. Specifically, 20 DAC portions d1 to d20 are divided into two blocks: block B1 consisting of DAC portions d1 to d10 and block B2 consisting of DAC portions d11 to d20.

Outputs of the ten DAC portions d1 to d10 in the block B1 are derived as output currents Iₒᵤₜ1 to Iₒᵤₜ10 and outputs of the ten DAC portions d11 to d20 in the block B2 are derived as output currents Iₒᵤₜ11 to Iₒᵤₜ20.

In this circuit, switch groups SW1 to SW4 are installed on the outputs of the DAC portions d1 to d20 and are turned on in sequence in such a way that no two switch groups remain ON simultaneously. Consequently, the output currents are averaged, with its correspondence to the DAC portions being switched by the switch groups SW1 to SW4, and are derived as the output currents Iₒᵤₜ1 to Iₒᵤₜ20.

In this example, as shown in FIG. 27 clearly, the correspondence between four DAC portions d1, d10, d11, and d20 and four output currents Iₒᵤₜ1, Iₒᵤₜ10, Iₒᵤₜ11, and Iₒᵤₜ20 are switched by the switches contained in the switch groups SW1 to SW4. The switch group SW1 includes switches SW11, SW12, SW13, and SW14; the switch group SW2 includes switches SW21, SW22, SW23, and SW24; the switch group SW3 includes switches SW31, SW32, SW33, and SW34; and the switch group SW4 includes switches SW41, SW42, SW43, and SW44.

In this example, as indicated by the arrows Y1 and Y2 as well as the arrows Y3 and Y4, the correspondence is switched in both directions in turns. Through the switching of the correspondence, time-division control is performed. In other words, output currents are controlled in such a way as to be averaged over time. This makes it possible to reduce trended variation of output currents in IC chips.

Regarding the DAC portions not shown in FIG. 27, the correspondence between four DAC portions and four output currents are similarly switched by the switches Sᵢⱼ (i=1 to 4; j=1 to 4) contained in the switch groups SW1 to SW4. Specifically, the correspondence between four DAC portions d2, d9, d12, and d19 and four output currents Iₒᵤₜ2, Iₒᵤₜ9, Iₒᵤₜ12, and Iₒᵤₜ19 are switched. Also, the correspondence between four DAC portions d3, d8, d13, and d18 and four output currents Iₒᵤₜ3, Iₒᵤₜ8, Iₒᵤₜ13, and Iₒᵤₜ18 are switched. Also, the correspondence between four DAC portions d4, d7, d14, and d17 and four output currents Iₒᵤₜ4, Iₒᵤₜ7, Iₒᵤₜ14, and Iₒᵤₜ17 are switched. Furthermore, the correspondence between four DAC portions d5, d6, d15, and d16 and four output currents Iₒᵤₜ5, Iₒᵤₜ6, Iₒᵤₜ15, and Iₒᵤₜ16 are switched.

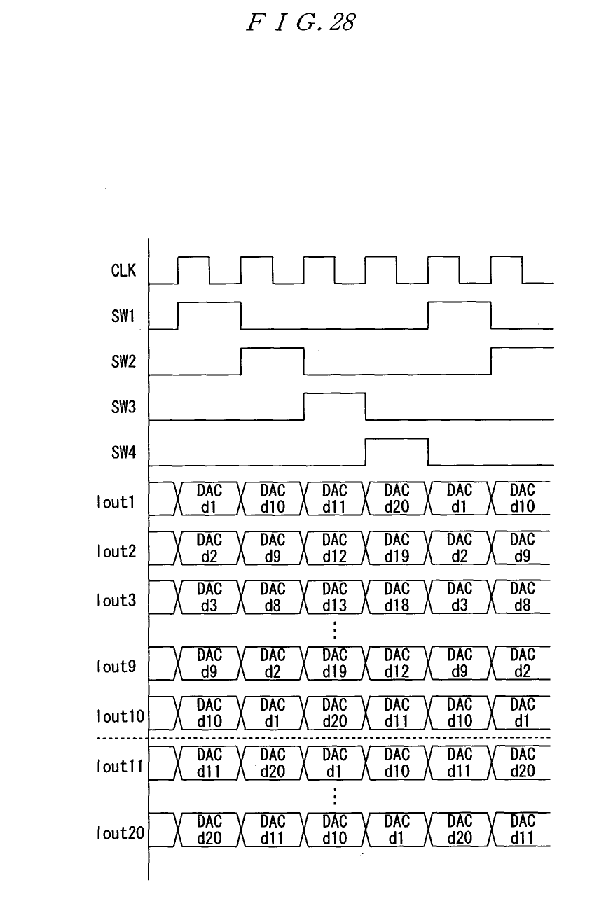

An example of timing to switch correspondence between outputs of DAC portions and output currents is shown in FIG. 28. The figure shows the states of the switch groups SW1 to SW4 as well as the outputs from the DAC portions d1 to d20 which constitute the output currents Iₒᵤₜ1 to Iₒᵤₜ20. Incidentally, reference character CLK in the figure denotes a clock.

Referring to FIG. 28, outputs of the four DAC portions d1, d10, d11, and d20 are averaged in a time-divided manner and synthesized into the output current Iₒᵤₜ1. Also, outputs of the four DAC portions d2, d9, d12, and d19 are averaged in a time-divided manner and derived as the output current Iₒᵤₜ2; and outputs of the four DAC portions d3, d8, d13, and d18 are averaged in a time-divided manner and derived as the output current Iₒᵤₜ3. Regarding the other output currents, outputs of four DAC portions are averaged in a time-divided manner and synthesized into an output current.

Each of the output currents Iₒᵤₜ1, Iₒᵤₜ10, Iₒᵤₜ11, and Iₒᵤₜ20 is synthesized from outputs of the DAC portions d1, d10, d11, and d20. However, when the switch group SW1 is ON, the output current Iₒᵤₜ1 is outputted from the DAC portion d1, the output current Iₒᵤₜ10 is outputted from the DAC portion d10, the output current Iₒᵤₜ11 is outputted from the DAC portion d11, and the output current Iₒᵤₜ20 is outputted from the DAC portion d20. Similarly, when the switch group SW2 is ON, the output current Iₒᵤₜ1 is outputted from the DAC portion d10, the output current Iₒᵤₜ10 is outputted from the DAC portion d1, the output current Iₒᵤₜ11 is outputted from the DAC portion d20, and the output current Iₒᵤₜ20 is outputted from the DAC portion d11; when the switch group SW3 is ON, the output current Iₒᵤₜ1 is outputted from the DAC portion d11, the output current Iₒᵤₜ10 is outputted from the DAC portion d20, the output current Iₒᵤₜ11 is outputted from the DAC portion dl, and the output current Iₒᵤₜ20 is outputted from the DAC portion d10; when the switch group SW4 is ON, the output current Iₒᵤₜ1 is outputted from the DAC portion d20, the output current Iₒᵤₜ10 is outputted from the DAC portion d11, the output current Iₒᵤₜ11 is outputted from the DAC portion d10, and the output current Iₒᵤₜ20 is outputted from the DAC portion d1; and so forth.

Other output currents are also synthesized from outputs of DAC portions in a time-divided manner through the operation of the switch groups. Thus, by operating a plurality of switches provided corresponding to a plurality of DAC portions, it is possible to reduce the above-described variation using a simple configuration.

Incidentally, the control signal used to switch the correspondence between DAC portions and output currents according to the timing chart such as the one shown in FIG. 28 is generated by a counter circuit or the like. For example, an N-stage ring counter is used (N=4 in the above example). An N-stage ring counter can be configured, for example, by using N stages of shift resisters connected in series and connecting the last-stage output to the first-stage input.

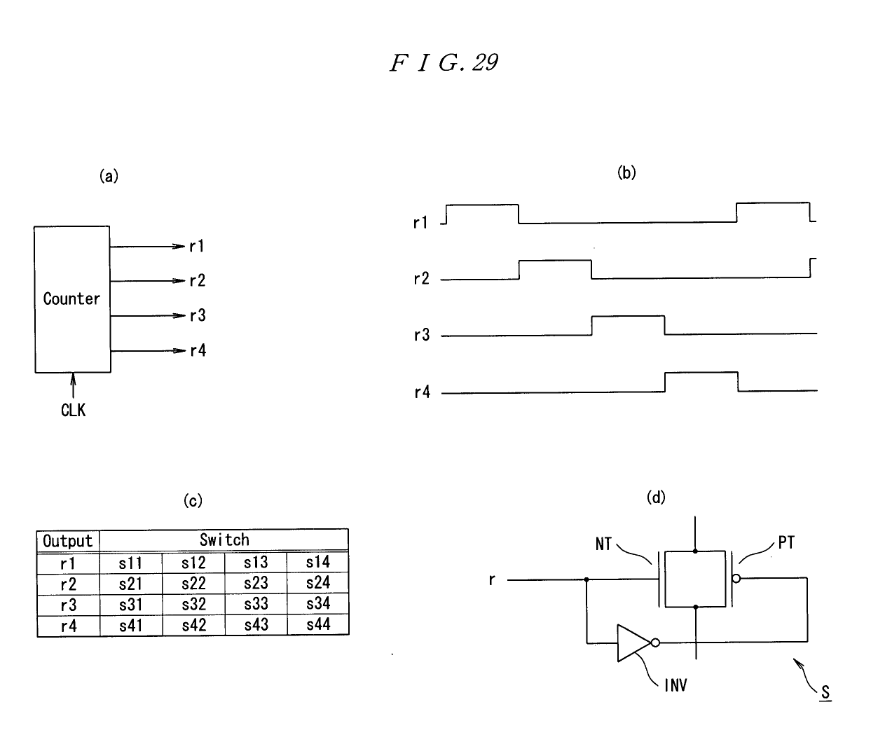

When an N-stage ring counter is used, waveforms of control signals r1 to r4 outputted from the ring counter shown in FIG. 29(a) change in such a way that the periods in which the signals are High shift in sequence as shown in FIG. 29(b). The control signals r1 to r4 whose waveforms change in this way are supplied to the switches in the switch groups SW1 to SW4.

Destinations of the control signals r1 to r4 are shown in FIG. 29(c). As shown in the figure, the control signal r1 is supplied to switches s11, s12, s13, and s14 in FIG. 27. Also, the control signal r2 is supplied to switches s21, s22, s23, and s24. Similarly, the control signal r3 is supplied to switches s31, s32, s33, and s34 while the control signal r4 is supplied to switches s41, s42, s43, and s44. As the control signals r1 to r4 are supplied to the switches in the switch groups SW1 to SW4, the operations shown in FIG. 28 can be performed.

Incidentally, each of the switches in the switch groups SW1 to SW4 is configured, for example, as shown in FIG. 29(d). In the figure, the switch consists of an NMOS (N-channel Metal oxide Semiconductor) transistor NT and PMOS (P-channel Metal oxide Semiconductor) transistor PT with the source terminals connected with each other and the drain terminals connected with each other. A control signal r is applied to the gate terminal of the NMOS transistor NT directly while it is applied to the gate terminal of the PMOS transistor PT after being inverted by an inverter INV.

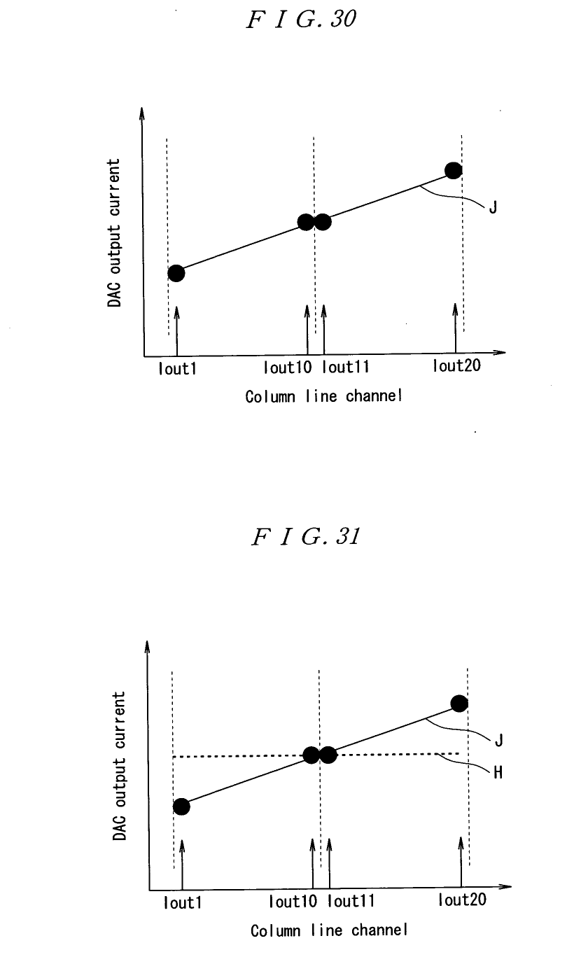

Now consider a conventional circuit in which the correspondence described above is not switched and trended variation of output currents in IC chips has characteristics shown in FIG. 30. The figure shows output current of DAC portions versus column line channels. In the figure, the location of a black circle ● moves upward as the column line channel changes from out put current Iₒᵤₜ1 through output current Iₒᵤₜ10 and output current Iₒᵤₜ11 to output current Iₒᵤₜ20. Thus, as indicated by the solid line J in the figure, the output current of DAC portions tends to increase gradually against column line channels.

When the circuit configuration of this embodiment is adopted, this characteristic takes the following form. Taking the output current Iₒᵤₜ1 as an example, the DAC portion d1, DAC portion d10, DAC portion d11, and DAC portion d20 are used to derive the output current Iₒᵤₜ1. Specifically, the outputs from the DAC portions are averaged in a time-divided manner to produce the output current Iₒᵤₜ1. In other words, a current is derived which is equivalent to (output of DAC portion d1+output of DAC portion d10+output of DAC portion d11+output of DAC portion d20)/4

As a result, the output currents indicated by the solid line J in FIG. 31 are averaged as indicated by the broken line H, reducing the trended variation of the output currents in IC chips. Other output currents can be averaged in a similar manner, reducing the trended variation of the output currents in IC chips.

This circuit can also reduce random current variation inherent to the DAC portions. This will be described below.

Let ΔI denote the random current variation of the DAC portions. ΔI is the same as the current variation of conventional DAC portions. Also, let ΔI₁ denote the random current variation of the DAC portions connected to the switch group SW1, let ΔI₂ denote the random current variation of the DAC portions connected to the switch group SW2, let ΔI3 denote the random current variation of the DAC portions connected to the switch group SW3, and let ΔI₄ denote the random current variation of the DAC portions connected to the switch group SW4. Then, the average variation is as follows:

Average variation=1/4×√(ΔI₁²+ΔI₂²+ΔI₃²+ΔI₄²)

If it is assumed that ΔI₁, ΔI₂, ΔI₃, and ΔI₄ are equal to ΔI,

Average variation=1√4×ΔI

Thus, the configuration of this circuit makes the amount of current variation smaller than that of the current variation 66 I of conventional DAC portions.

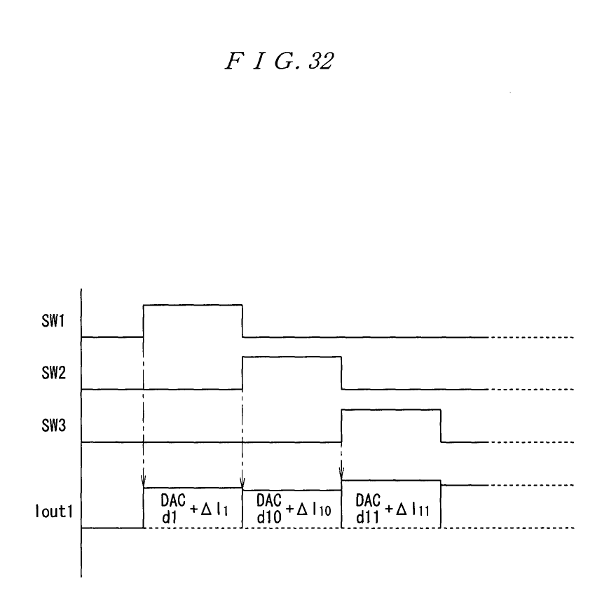

FIG. 32 shows a timing chart which takes into consideration random current variation in DAC portions. The figure shows relationship between the output current Iₒᵤₜ1 and switch groups as a representative example.

As shown in the figure, when the switch group SW1 is ON, the output current Iₒᵤₜ1 equals the output of the DAC portion d1 plus the current variation ΔI₁. Also, when the switch group SW2 is ON, the output current Iₒᵤₜ1 equals the output of the DAC portion d10 plus the current variation ΔI₁₀. Similarly, for a switch group which is ON, the output current Iₒᵤₜ1 equals the output of the DAC portion dk (k=1, 10, 11, 20, etc.) plus the current variation ΔIₖ. The other currents are also calculated by adding current variation to the output of the DAC portions. Thus, even if there are random current variations, the amount of current variation can be reduced by averaging the outputs in a time-divided manner as described above.

Incidentally, although in the configuration example shown in FIG. 27, the plurality of DAC portions are divided into two blocks, the number of blocks is not limited to two. Besides, the configuration requires twice as many switch groups as there are blocks of DAC portions.

Also, the bit count used by the DAC portions is not limited to the one described above. The number of channels in the DAC portions is not limited to the one used in the above example either. Regarding the circuit configuration of the DAC portions, either PMOS transistors or NMOS transistors may be used.

Also, although the pixel elements composing the display panel are EL elements in the example described above, it is obvious that the present invention also applies to cases in which other elements are used.

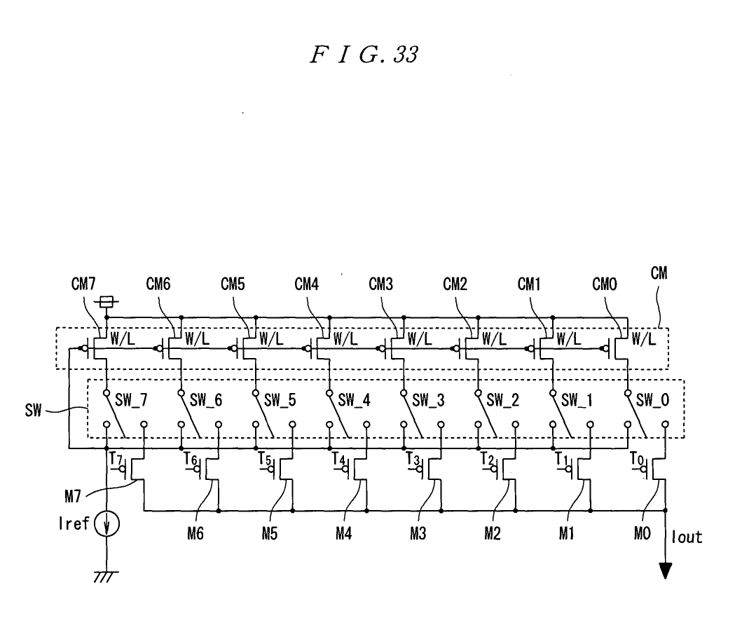

FIG. 33 is a block diagram showing main components of a sixth embodiment of a display panel drive circuit according to the present invention. The figure shows a configuration example in which a 3-bit DAC circuit is used. In such a 3-bit DAC circuit, a current mirror circuit requires one MOS transistor (hereinafter referred to as a MOSTr) in a BIAS portion and seven (4+2+1) MOSTrs in a DAC portion for a total of eight. Thus, the display panel drive circuit shown in FIG. 33 comprises eight MOSTrs M0 to M7, a switch circuit SW consisting of switches SW0 to SW7 corresponding to the MOSTrs M0 to M7, and a current mirror circuit CM consisting of eight MOSTrs CM0 to CM7.

Control signals T0 to T7 are supplied to gate terminals of the eight MOSTrs M0 to M7, respectively, as described below. Thus, the MOSTrs M0 to M7 are turned on and off by the respective control signals T0 to T7.

Each of the switches SW0 to SW7 which compose the switch circuit SW operates to electrically connect respective one of the eight MOSTrs CM0 to CM7 composing the current mirror circuit CM with either the reference current source I_{ref} or the respective one of the MOSTrs M0 to M7. When any of the MOSTrs CM0 to CM7 composing the current mirror circuit CM is connected to the respective one of the MOSTrs M0 to M7, an output current Iₒᵤₜ is supplied to a display panel not shown. Specifically, the MOSTrs CM0 to CM7 composing the current mirror circuit CM operate as a mirror source when electrically connected to the reference current source I_{ref} by the operation of the switches SW0 to SW7, and operate as a DAC circuit for generating the output current Iₒᵤₜ, i.e., a drive signal to be supplied to pixels, when connected to the corresponding MOSTrs M0 to M7. Incidentally, it is assumed that the eight MOSTrs CM0 to CM7 composing the current mirror circuit CM have the same channel width to channel length ratio W/L.

With this configuration, the circuit uses all the eight MOSTrs M0 to M7 as the BIAS portion with a major current variation by switching among them in sequence with the switches SW0 to SW7. By averaging the current variations of all the eight MOSTrs M0 to M7 over time in this way, it is possible to reduce the current variation of the entire DAC circuit.

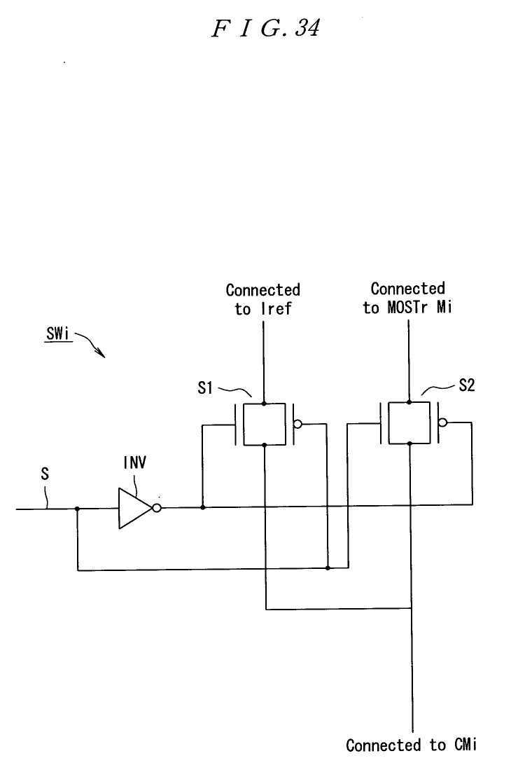

Each of the switches SWi (i=0 to 7, the same applies hereinafter) composing the switch circuit SW can be configured, for example, as shown in FIG. 34. In other words, it comprises analog switches S1 and S2 as shown in the figure. Each of the analog switches S1 and S2 consists of a p-channel MOSTr and n-channel MOSTr which share both the source and drain. The analog switch S1 is connected to the reference current source I_{ref} while the analog switch S2 is connected to a MOSTr Mi.

The p-channel MOSTr constituting the analog switch S1 is fed a control signal S as it is while the n-channel MOSTr is fed the control signal S inverted by an inverter INV. On the other hand, p-channel MOSTr constituting the analog switch S2 is fed the control signal S inverted by the inverter INV while the n-channel MOSTr is fed a control signal S as it is. With this circuit connection, when the control signal S is Low, the analog switch S1 is ON (conducting) and the analog switch S2 is OFF (non-conducting). On the other hand, when the control signal S is High, the analog switch S2 is ON (conducting) and the analog switch S1 is OFF (non-conducting).

Thus, depending on the state of the control signal S, either the MOSTrs Mi which correspond to the switches SWi or the reference current source I_{ref} is connected electrically to the MOSTrs CMi (i=0 to 7, the same applies hereinafter) which compose the current mirror circuit CM.

The control signal S supplied to the switches SWi is generated by a counter circuit or the like.

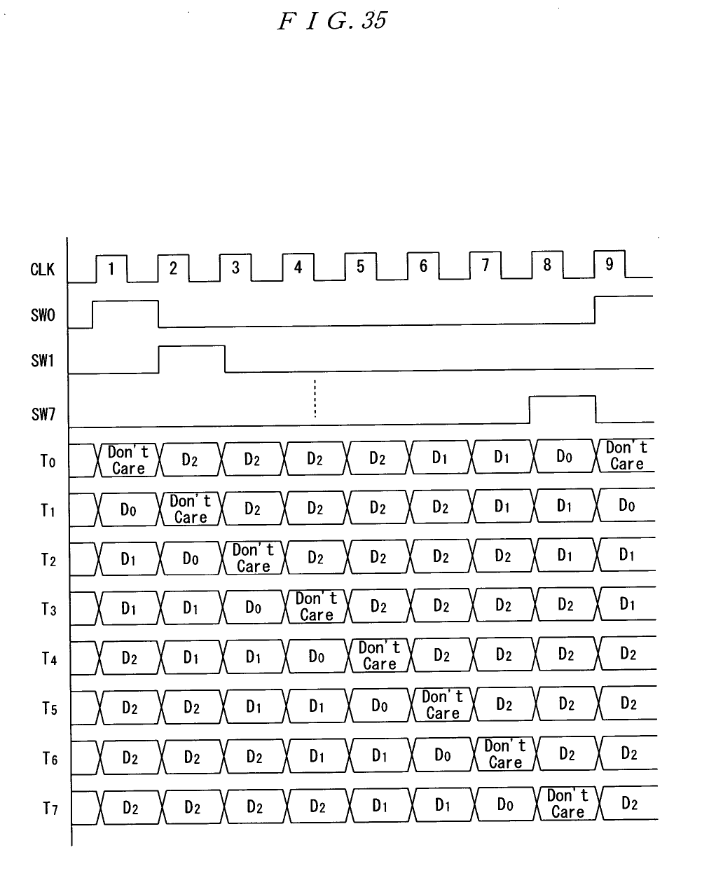

Returning to FIG. 33, the control signals T0 to T7 shown in the figure are generated being timed as shown in FIG. 35 using the control signal (the control signal S described above) supplied to the switches SWi composing the switch circuit SW and data signals D2 to D0 (3-bit in this example) from the DAC portion.

FIG. 35 is a timing chart showing a clock CLK, the ON/OFF states of the switches SWi which compose the switching circuit SW, and control signals T0 to T7. The switch SWi is ON (conducting) when the waveform in the figure is High, and is OFF (non-conducting) when the waveform is Low. As shown in the figure, when the switch SWi is conducting, the corresponding MOSTr Mi is turned on and off by the control signal Ti. At this time, 3-bit pixel data D0 to D2 are supplied as control signals to the MOSTrs M0 to M7 except the MOSTr Mi which corresponds to the switch SWi.

For example, when the switch SW0 is conducting, the MOSTr M0 which corresponds to the switch SW0 is turned on and off by the control signal T0. The MOSTrs M1 to M7 other than the MOSTr M0 which corresponds to the switch SW0 are supplied with the 3-bit pixel data D0 to D2 as the control signals T1 to T7. The MOSTr M1 is supplied with the pixel data D0 as the control signal T1. The MOSTrs M2 and M3 are supplied with the pixel data D1 as the control signals T2 and T3. The MOSTrs M4 to M7 are supplied with the pixel data D2 as the control signals T4 to T7.

Also, when the switch SW1 is conducting, the MOSTr M1 which corresponds to the switch SW1 is turned on and off by the control signal T1. The MOSTrs M2 to M7 and M0 other than the MOSTr M1 which corresponds to the switch SW1 are supplied with the 3-bit pixel data D0 to D2 as control signals T2 to T7 and T0. The MOSTr M2 is supplied with the pixel data D0 as the control signal T2. The MOSTrs M3 and M4 are supplied with the pixel data D1 as the control signals T3 and T4. The MOSTrs M5 to M7 and M0 are supplied with the pixel data D2 as the control signals T5 to T7 and T0.

Similarly, the MOSTr Mi which corresponds to the conducting switch SWi is turned on and off by the control signal Ti. The MOSTrs other than the MOSTr Mi which corresponds to the conducting switch SWi are supplied with the 3-bit pixel data D0 to D2 as control signals. In other words, at least one of n transistors is connected directly to the reference current source to supply a bias signal and the other transistors operate as a DAC circuit to generate drive signals to be supplied to the pixels using the bias signal, wherein the transistor which supplies the bias signal is changed in sequence in a time-divided manner.

In this way, the transistor which operates as the BIAS portion is changed in sequence in such a way that all the eight MOSTrs M0 to M7 are assigned in turns to the BIAS portion with a major current variation.

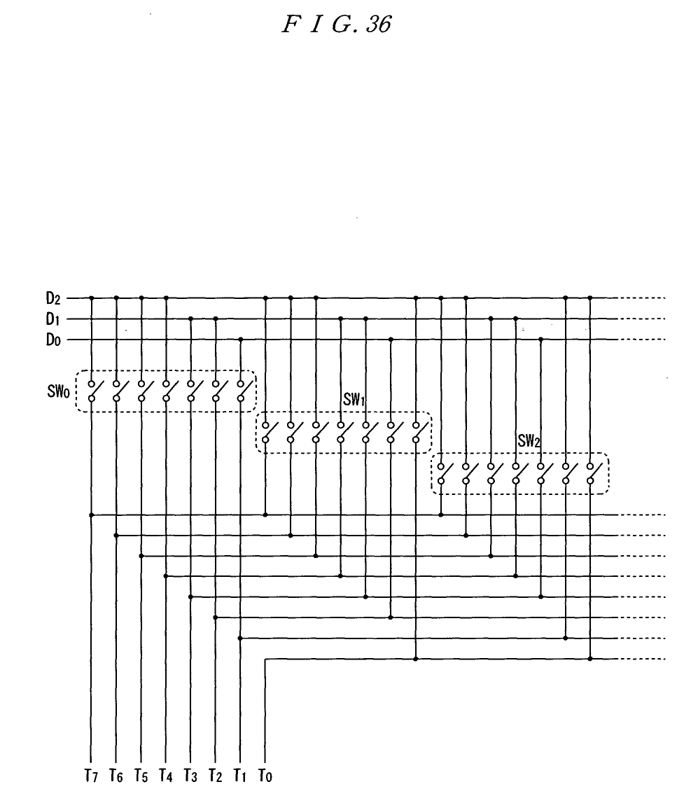

A configuration example of a circuit which generates the control signals T0 to T7 supplied to the gate terminals of the MOSTrs M0 to M7 in FIG. 33 will be described with reference to FIG. 36. Switches SW0, SW1, SW3, . . . which are fed the 3-bit data signals D2 to D0 are provided in the circuit shown in FIG. 36. The switch SW0 generates the control signals other than the control signal T0 using the 3-bit data signals D2 to D0. Also, the switch SW1 generates the control signals other than the control signal T1 using the 3-bit data signals D2 to D0. Also, the switch SW2 generates the control signals other than the control signal T2 using the 3-bit data signals D2 to D0. Similarly, the switch SWk (k=0 to 7) generates the control signals other than the control signal Tk using the 3-bit data signals D2 to D0. This configuration makes it possible to generate the control signal T0 to T7 shown in FIG. 35.

Let ΔI0 denote the current variation which occurs when the MOSTr CM0 used for the current mirror and corresponding to the SW0 is used as the BIAS portion and let ΔI1 denote the current variation which occurs when the MOSTr CM1 used for the current mirror and corresponding to the SW1 is used as the BIAS portion. Similarly, let ΔI2 denote the current variation which occurs when the MOSTr CM2 is used as the BIAS portion, let 66 I3 denote the current variation which occurs when the MOSTr CM3 is used as the BIAS portion, let ΔI4 denote the current variation which occurs when the MOSTr CM4 is used as the BIAS portion, let ΔI5 denote the current variation which occurs when the MOSTr CM5 is used as the BIAS portion, let ΔI6 denote the current variation which occurs when the MOSTr CM6 is used as the BIAS portion, and let ΔI7 denote the current variation which occurs when the MOSTr CM7 is used as the BIAS portion. Then, the average variation is as follows:

Average variation=1/8×√(ΔI₀²+ΔI₁² . . . +ΔI₇²)

If it is assumed that ΔI₀, ΔI₁, . . . , and ΔI₇ are equal to ΔI,

Average variation=1√8×ΔI

Thus, the current variation ΔI is smaller than that of conventional circuits.

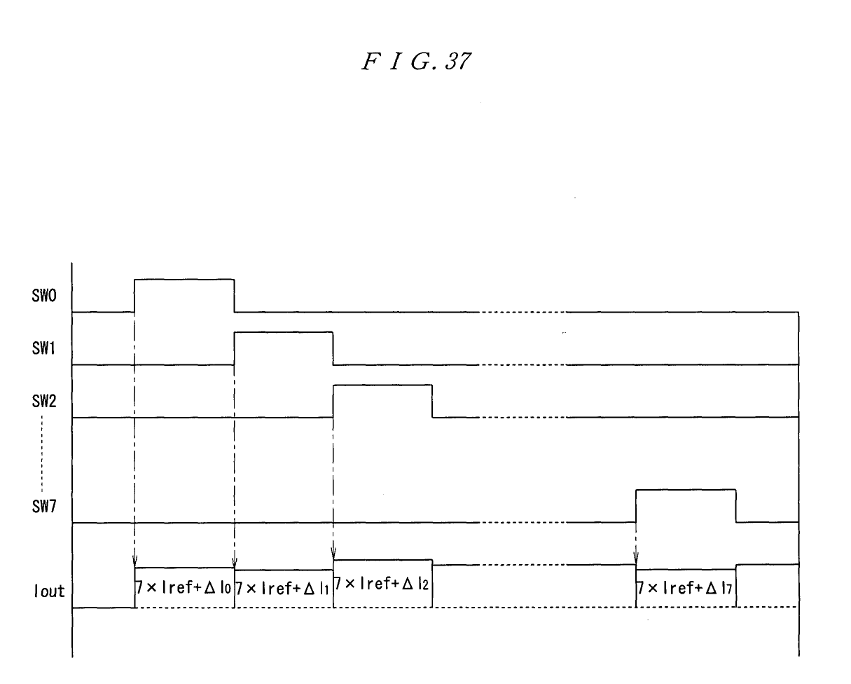

A timing chart which shows relationship between the ON/OFF states of the switches SWi and the output current Iₒᵤₜ when all the data D0, D1, and D2 in the DAC portion are High (or in full code) is shown in FIG. 37. As shown in the figure, the output current Iₒᵤₜ is given by

Iₒᵤₜ=7×I_{ref}+ΔIᵢ

Thus, it contains a current variation of ΔIᵢ.

In the case of an n-bit DAC circuit, the number of MOSTrs in the DAC portion is given by

2ⁿ⁻¹+2ⁿ⁻²+ . . . +2⁰=Σ2ⁱ

where Σ is the sum total of i=0 to n−1 (the same applies hereinafter). Thus, the total of MOSTrs in the DAC portion is Σ2ⁱ.

Hence, the average value of current variations is given by

(Σ2ⁱ⁺¹)^{-1/2}×ΔI

In this way, an accurate DAC circuit which can reduce variations between adjacent channels can be implemented. Incidentally, it is obvious that variations between adjacent channels can be reduced regardless of the bit count used by the DAC portion.

Although a PMOS DAC circuit has been cited as an example, it is obvious that the present invention also applies to NMOS DAC circuits.

Also, although the pixel elements composing the display panel are EL elements in the example described above, it is obvious that the present invention also applies to cases in which other elements are used.

Industrial Applicability

According to the first embodiment described above, when an anode line drive circuit is constructed from a plurality of IC chips, dummy drive output and proper drive output of the adjoining IC chip are switched in predetermined cycles and supplied to a drive line to reduce luminance differences in display areas caused by differences in current driving capacity among the IC chips and prevent degradation of image quality.

According to the second embodiment described above, correspondence between a plurality of IC chips and drive current sources are switched in predetermined cycles, which has the effect of reducing current variation in a current mirror. Also, variation in reference current among the plurality of IC chips is eliminated, providing uniform emission luminance on a display panel.

According to the third embodiment described above, a transistor which serves as a reference current source is changed periodically, reducing current variation in a current mirror and eliminating variation in reference current among a plurality of IC chips, thereby providing uniform emission luminance on a display panel.

According to the fourth embodiment described above, since an averaged current is supplied to a plurality of IC chips instead of the same current, even if there are variations among currents outputted from the IC chips, each of the IC chips operates on the averaged current in the long run, eliminating variation among reference currents. This makes it possible to obtain uniform emission luminance on a display panel.

According to the fifth embodiment described above, by switching the correspondence between a plurality of DAC portions and output currents in sequence in a time-divided manner, it is possible to reduce trended variation of the output currents in IC chips and decrease random current variations.

According to the sixth embodiment described above, a transistor which supplies a bias signal is changed in sequence in a time-divided manner and other transistors operate as a circuit to generate drive signals to be supplied to pixels using the bias signal, making it possible to implement an accurate DAC circuit and reduce variations between adjacent channels.

1. A display panel drive circuit which supplies current to a plurality of drive line groups for driving a plurality of pixel elements which compose a display panel, characterized in that current which flows through each of the plurality of drive line groups is switched in predetermined cycles.

2. The display panel drive circuit according to claim 1, characterized in that the plurality of pixel elements which compose the display panel are electroluminescent elements.

3. The display panel drive circuit according to claim 1, characterized in that: the plurality of drive line groups are constructed in a plurality of different IC chips; and each of the plurality of IC chips comprise a plurality of drive current supplying means for supplying a drive current to each of the plurality of IC chips and switching means for switching correspondence between the plurality of IC chips and the plurality of drive current supplying means in predetermined cycles.

4. The display panel drive circuit according to claim 3, characterized in that the switching means is formed in the IC chips.

5. The display panel drive circuit according to claim 3, characterized in that:
of the plurality of drive line groups, first and second drive line groups are provided in a first and second IC chips, respectively; and
the switching means receives a first drive output belonging to a drive output group of the first IC chip and a second drive output belonging to a drive output group of the second IC chip and supplies them to a drive line which belongs to the first drive line group and adjoins the second drive line group by switching between them in predetermined cycles.

6. The display panel drive circuit according to claim 5, characterized in that: the second IC chip has a dummy drive output which does not correspond to any of the drive lines composing the second drive line group; and the dummy drive output is fed as the second drive output into the switching means.

7. The display panel drive circuit according to claim 3, characterized by further comprising a reference current source shared by the plurality of drive current supplying means, with the reference current source and drive current supplying means composing a current mirror circuit.

8. The display panel drive circuit according to claim 3, characterized in that: the plurality of IC chips are three or more in number; and the correspondence between the drive current sources and the IC chips are switched in rotation in predetermined cycles.

9. The display panel drive circuit according to claim 1, characterized by comprising: a plurality of reference current sources each of which generates a reference current; a plurality of drive current generating means for forming a current mirror circuit in conjunction with the plurality of reference current sources to generate current and driving the first and second drive line groups; and switching means for switching correspondence between the plurality of reference current sources and the plurality of drive current generating means in predetermined cycles.

10. The display panel drive circuit according to claim 9, characterized in that the plurality of reference current sources and the plurality of drive current generating means are contained in a plurality of IC chips.

11. The display panel drive circuit according to claim 10, characterized in that the switching means switches electrical connection between the plurality of reference current sources and plurality of IC chips using pulses with a duty ratio of 1/N, where N is the number of IC chips.

12. The display panel drive circuit according to claim 10, characterized in that it: comprises a plurality of digital-to-analog converter portions and a single biasing portion which gives bias signals to the digital-to-analog converter portions; supplies a plurality of output currents derived from the plurality of digital-to-analog converter portions to the plurality of drive line groups; and comprises switching means for switching correspondence between the plurality of digital-to-analog converter portions and the plurality of derived output currents in a time-divided manner.

13. The display panel drive circuit according to claim 12, characterized in that the switching means comprises a plurality of switches corresponding to the plurality of digital-to-analog converter portions and switches correspondence between the plurality of digital-to-analog converter portions and the plurality of derived output currents in a time-divided manner by operating the plurality of switches in sequence.

14. A display panel drive circuit which supplies current to a plurality of IC chips and drives the display panel by the supplied current, characterized by comprising drive current supplying means for supplying drive current to each of the plurality of IC chips; and switching means for switching correspondence between the IC chips and the drive current supplying means in predetermined cycles.

15. The display panel drive circuit according to claim 14, characterized by further comprising a reference current source shared by the plurality of drive current supplying means, with the reference current source and drive current supplying means composing a current mirror circuit.

16. The display panel drive circuit according to claim 14, characterized in that: the plurality of IC chips are three or more in number; and the correspondence between the drive current sources and the IC chips are switched in rotation in predetermined cycles.

17. The display panel drive circuit according to claim 14, characterized in that the display panel may be composed of a plurality of electroluminescent elements driven by drive output produced by the respective IC chips.

18. A display panel drive circuit which comprises first and second IC chips and supplies drive output groups from the first and second IC chips to first and second IC drive line groups for driving a plurality of pixel elements which compose the display panel, characterized by comprising a switching circuit which receives a first drive output belonging to a drive output group of the first IC chip and a second drive output belonging to a drive output group of the second IC chip and supplies them to a drive line which belongs to the first drive line group and adjoins the second drive line group by switching between them in predetermined cycles.

19. The display panel drive circuit according to claim 18, characterized in that the switching means is formed in the IC chips.

20. The display panel drive circuit according to claim 18, characterized in that: the second IC chip has a dummy drive output which does not correspond to any of the drive lines composing the second drive line group; and the dummy drive output is fed as the second drive output into the switching means.

21. The display panel drive circuit according to claim 18, characterized in that the plurality of pixel elements which compose the display panel are electroluminescent elements.

22. A display panel drive circuit which provides current for driving a plurality of pixel elements which compose a display panel, comprising: one transistor which serves as a reference current source; N transistors (N is a natural number) which compose a current mirror circuit in conjunction with the one transistor; and switching means for selecting a transistor to serve as a reference current source from the N+1 transistors and switching to it periodically, characterized in that outputs from the remaining N transistors are derived as drive output for the display panel.

23. The display panel drive circuit according to claim 24, characterized in that the outputs from the remaining N transistors are merged into one when derived as drive output for the display panel.

24. The display panel drive circuit according to claim 22 or 23, characterized in that the display panel is composed of electroluminescent elements driven by the drive output.

25. A display panel drive circuit comprising: a plurality of reference current sources each of which generates a reference current; and a plurality of drive current generating means which generate current by mirroring the plurality of reference current sources and provide current for driving a plurality of pixel elements which compose a display panel, characterized in that the drive current generating means are contained in a plurality of IC chips and comprise switching means for switching correspondence between the plurality of reference current sources and the plurality of IC chips in predetermined cycles.

26. The display panel drive circuit according to claim 25, characterized in that the switching means switches electrical connection between the plurality of reference current sources and plurality of IC chips using pulses with a duty ratio of 1/N, where N is the number of IC chips.

27. The display panel drive circuit according to claim 25 or 26, characterized in that the display panel may be composed of a plurality of electroluminescent elements driven by drive output produced by the respective IC chips.

28. A display panel drive circuit characterized in that: at least one of a plurality of transistors supplies bias signals being connected directly with a reference current source for a current mirror while the other transistors operate as a circuit which generates drive signals to be supplied to pixels using the bias signals; and the display panel drive circuit comprises a switching means for changing, in a time-divided manner, the transistor which supplies bias signals.

29. The display panel drive circuit according to claim 28, characterized in that: the switching means comprises a plurality of switches corresponding to the plurality of transistors;
at least one of the plurality of switches operates so that the corresponding transistor is connected with the reference current source to act as a mirror source of a current mirror circuit; and
all the other switches are operated so that their corresponding transistors conduct to act as circuits for generating the drive signals.

30. A display panel drive circuit characterized in that it: comprises a plurality of digital-to-analog converter portions and a single biasing portion which gives bias signals to the digital-to-analog converter portions; supplies a plurality of output currents derived from the plurality of digital-to-analog converter portions to pixels to drive a display panel; and comprises switching means for switching correspondence between the plurality of digital-to-analog converter portions and the plurality of derived output currents in a time-divided manner.

31. The display panel drive circuit according to claim 30, characterized in that the switching means comprises a plurality of switches corresponding to the plurality of digital-to-analog converter portions and switches correspondence between the plurality of digital-to-analog converter portions and the plurality of derived output currents in a time-divided manner by operating the plurality of switches in sequence.
